(19) United States
(12) Patent Application Publication
(10) Pub. No.: US 2025/0266346 A1
(43) Pub. Date: Aug. 21, 2025

(54) SEMICONDUCTOR DEVICES AND METHODS OF MANUFACTURING SEMICONDUCTOR DEVICES

(71) Applicant: Amkor Technology Singapore Holding Pte. Ltd.

(72) Inventors: Sang Hyun Jin, Incheon (KR); Hyun Goo Cha, Incheon (KR); Yun Kyung Jeong, Incheon (KR); Jin Suk Jeong, Incheon (KR)

(73) Assignee: Amkor Technology Singapore Holding Pte. Ltd., (omitted)

(21) Appl. No.: 18/583,737

(22) Filed: Feb. 21, 2024

(51) Int. Cl. H01L 23/522; H01L 21/768; H01L 23/528

(52) U.S. Cl. CPC H01L 23/5226; H01L 21/76877; H01L 23/5283

(57) ABSTRACT

In one example, a semiconductor device can include a first dielectric layer comprising an inner wall that defines a via. A seed layer can be disposed over the first dielectric layer and in the via. A first conductor can be disposed over the seed layer and in the via, and the first conductor can have a cylindrical geometry. A second conductor can be disposed over the first conductor and the first dielectric layer. The second conductor can extend into a gap defined between the inner wall of the first dielectric layer and a lateral side of the first conductor. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic component.

FIGS. 2A to 2R show an example method for manufacturing an electronic component.

FIG. 3A shows a cross-sectional view of an example electronic component.

FIG. 3B shows a top-down view of the example electronic component of FIG. 3A taken along the line 3B-3B in FIG. 3A.

FIG. 4 shows a cross-sectional view of an example electronic device.

FIG. 5 shows a cross-sectional view of an example electronic device.

FIG. 6 shows a cross-sectional view of an example electronic device.

FIG. 7 shows a cross-sectional view of an example electronic device.

FIG. 8 shows a cross-sectional view of an example electronic component.

FIGS. 9A to 9N show an example method for manufacturing an example electronic component.

FIG. 10 shows a cross-sectional view of an example electronic device.

FIG. 11 shows a cross-sectional view of an example electronic device.

FIG. 12 shows a cross-sectional view of an example electronic device.

FIG. 13 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. For example, the steps recited in any of the method or process descriptions may be executed in any order and are not necessarily limited to the order presented. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. As used herein, the term “coupled” can refer to an electrical coupling or a mechanical coupling.

### DESCRIPTION

An example method of making a semiconductor device can include the step of providing a first dielectric layer. An inner wall of the first dielectric layer can define a first via. A first photoresist can be provided over the first dielectric layer and in the first via. An inner wall of the first photoresist can define a second via extending into the first via. A first conductor can be provided in the second via, and a first gap can be defined between a lateral side of the first conductor and the inner wall of the first dielectric layer. The first photoresist can be removed from the first gap defined between the lateral side of the first conductor and the inner wall of the first dielectric layer. A second photoresist can be provided over the first dielectric layer and can define a third via over the first conductor. A second conductor can be provided in the third via. The second conductor can extend into the first gap defined between the lateral side of the first conductor and the inner wall of the first dielectric layer.

Another example method of making a semiconductor device can include the steps of providing a first conductor, providing a second conductor protruding above the first conductor, and providing a first dielectric layer. A first gap can be defined between an inner wall of the first dielectric layer and a lateral side of the second conductor. A first seed layer can be provided over the second conductor, over the first dielectric layer, and in the first gap. A third conductor can be provided over the first seed layer. The third conductor can extend into the first gap defined between the lateral side of the second conductor and the inner wall of the first dielectric layer.

An example semiconductor device can include a first dielectric layer comprising an inner wall that defines a via. A seed layer can be disposed over the first dielectric layer and in the via. A first conductor can be disposed over the seed layer and in the via, and the first conductor can have a cylindrical geometry. A second conductor can be disposed over the first conductor and the first dielectric layer. The second conductor can extend into a gap defined between the inner wall of the first dielectric layer and a lateral side of the first conductor.

Other examples are included in the present disclosure. Such examples may be found in the figures, in the claims, or in the description of the present disclosure.

Examples of devices and methods described below tend to prevent the collapse of traces formed above conductive layers and dielectric layers. The conductive structures can have widths wider than a maximum via fill width and a top side that is substantially flat. The conductive structures can be formed in phases to produce the substantially flat top side. Dielectric layers subsequently formed over the substantially flat top side of a conductive structure tend to also have substantially flat top sides. Traces formed over the substantially flat top sides of dielectric layers tend to avoid collapsing. As used herein to describe a side or a surface characteristic, “substantially flat” can mean a surface having a maximum dimple depth or surface variation of about 4-6 micrometers (μm), about 3-7 μm, about 2-8 μm, or about 1-10 μm. As used herein with units of distance, the term “about” can mean +/−5%, +/−10%, +/−15%, +/−20%, or +/−25%.

In some prior art, traces could collapse due to underlying dimples (e.g., depressions or recesses) in the top sides of the dielectric layers. The dimples in dielectric structures of the prior art would appear when the top sides of dielectric layers reflected dimples in the top side of underlying conductive structures. Dimples could form in the underlying conductive structures of the prior art when attempting to fill a wide via (e.g., wider than a maximum fill width) with conductive material. Examples of devices and methods described below tend to limit the formation of dimples by depositing conductive structures in wide vias using steps described below.

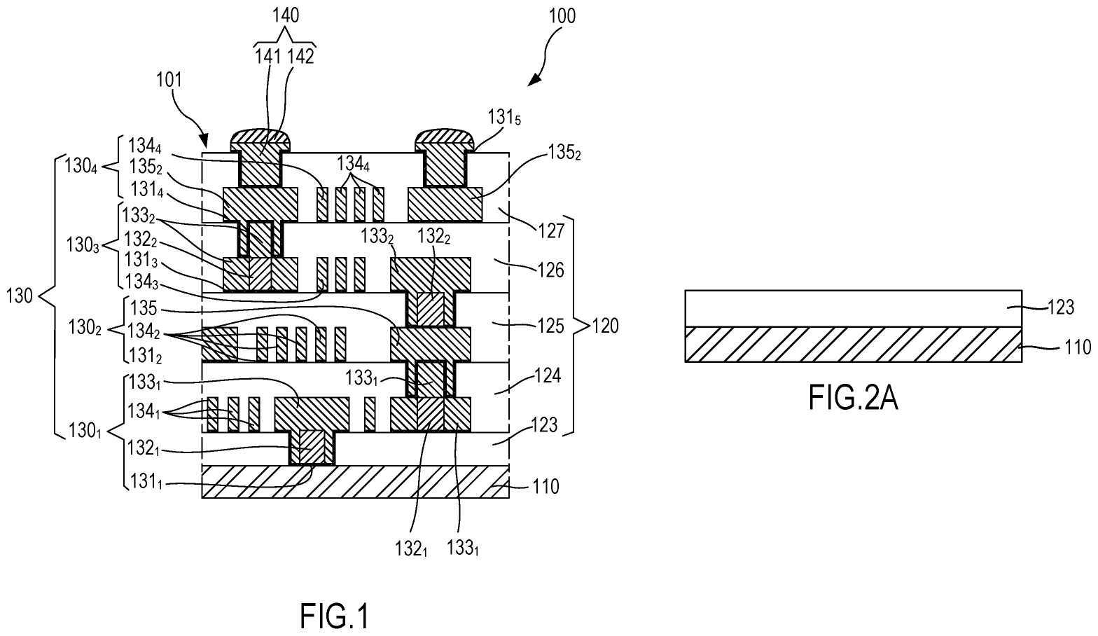

Referring now to FIG. 1, a cross-sectional view of an example electronic component 100 is shown. In the example shown in FIG. 1, electronic component 100 can comprise substrate 110 and redistribution structure 101. Redistribution structure 101 can comprise dielectric structure 120, conductive structure 130, and component interconnects 140.

Conductive structure 130 can include one or more conductive patterns, such as conductive pattern 130₁, conductive pattern 130₂, conductive pattern 130₃, and conductive pattern 130₄, interleaved with one or more dielectric layers, such as dielectric layer 123, 124, 125, 126, and 127, of dielectric structure 120. Conductive pattern 130₁ can comprise seed layer 131₁, conductors 132₁, conductors 133₁, and traces 134₁. Conductive pattern 130₂ can comprise seed layer 131₂, traces 134₂, and conductors 135₁. Conductive pattern 130₃ can comprise seed layer 131₃, conductors 132₂, conductors 133₂, and traces 134₃. Conductive pattern 130₄ can comprise seed layer 131₄, traces 134₄, and conductors 135₂. Component interconnects 140 can each comprise contact pad 141 and terminal tip 142. In some examples, conductive structure 130 can electrically couple component interconnects 140 to substrate 110. In some examples, redistribution structure 101 can provide electrical coupling between external electrical components and substrate 110.

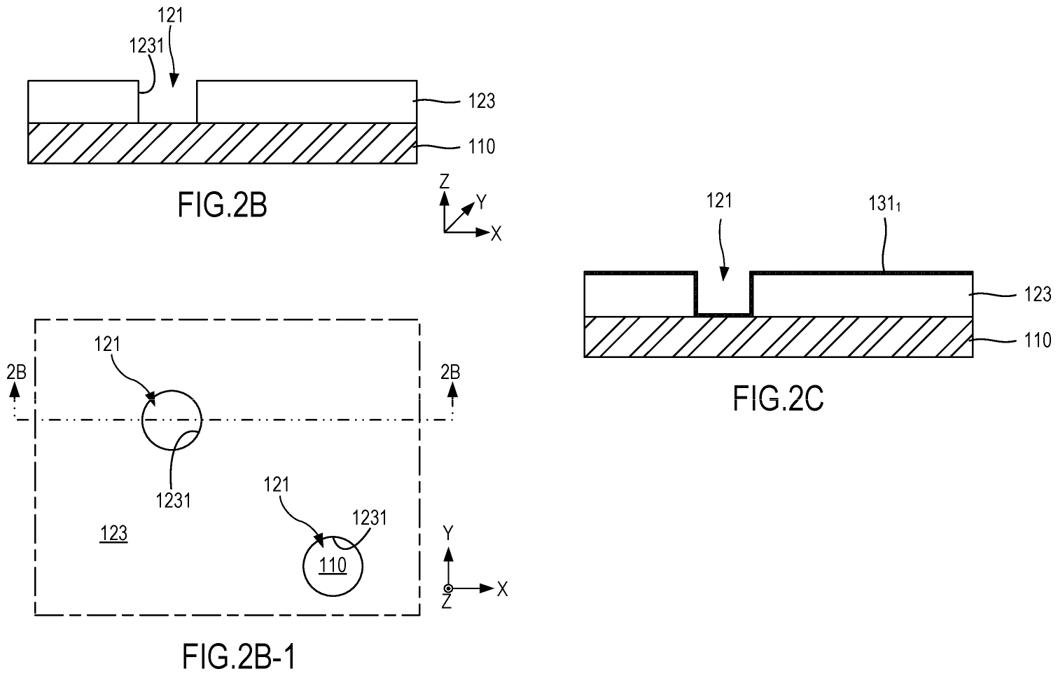

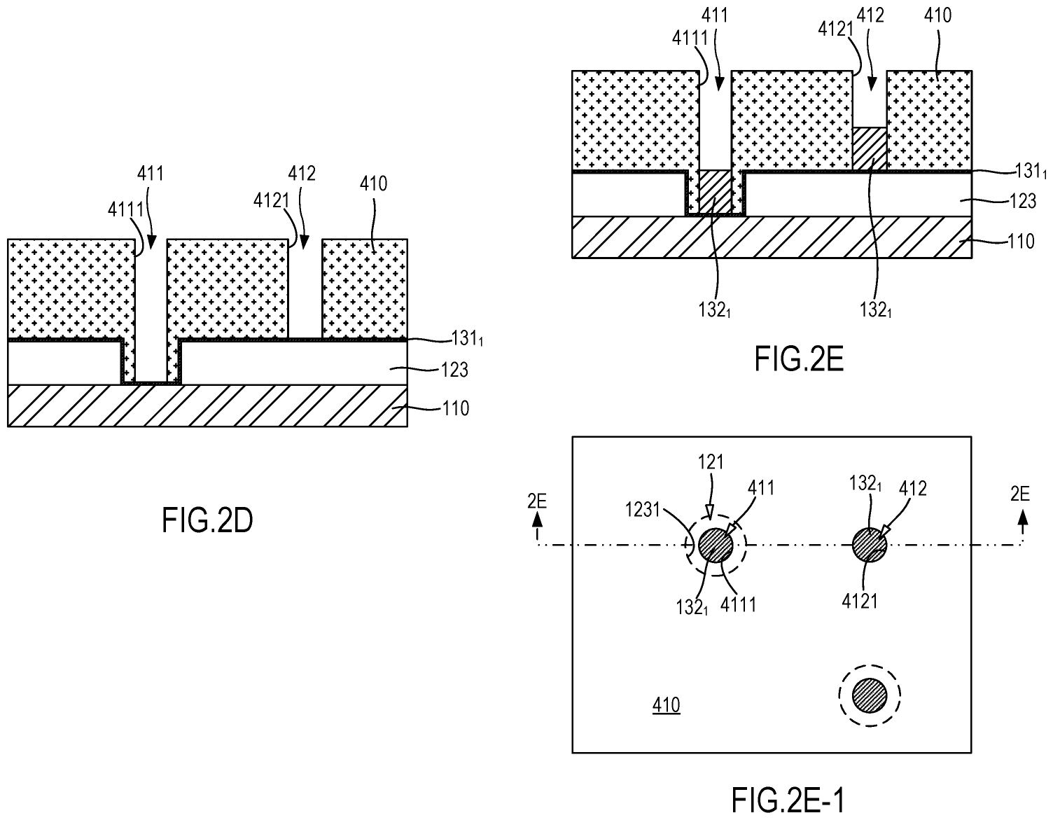

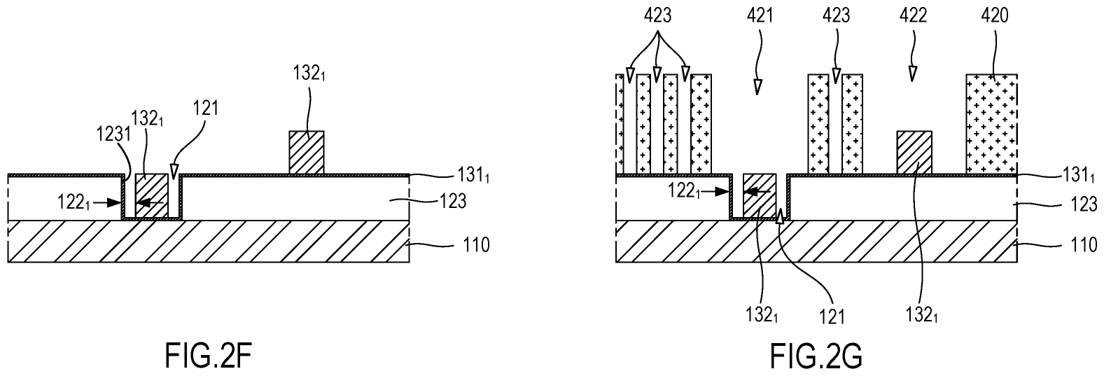

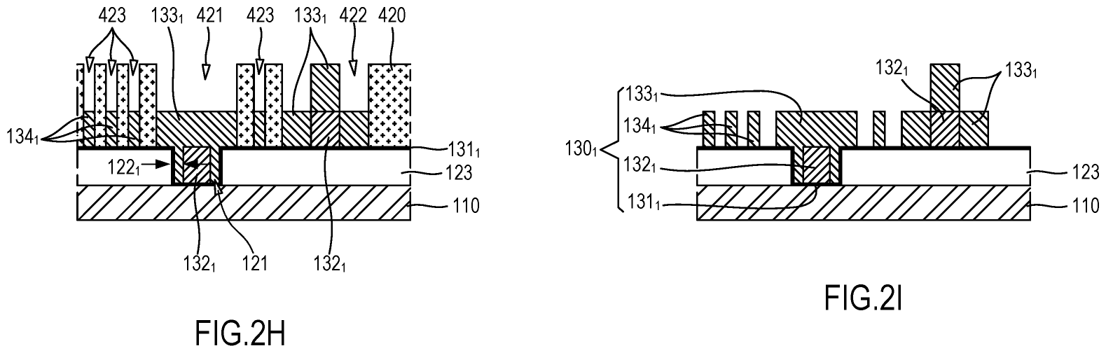

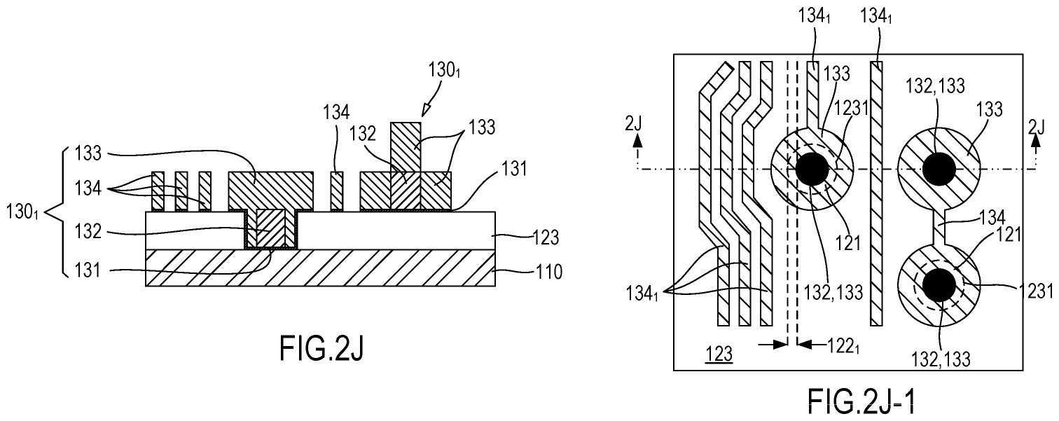

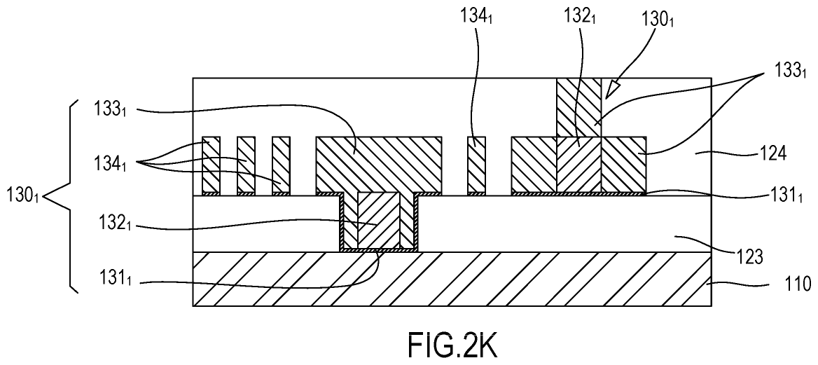

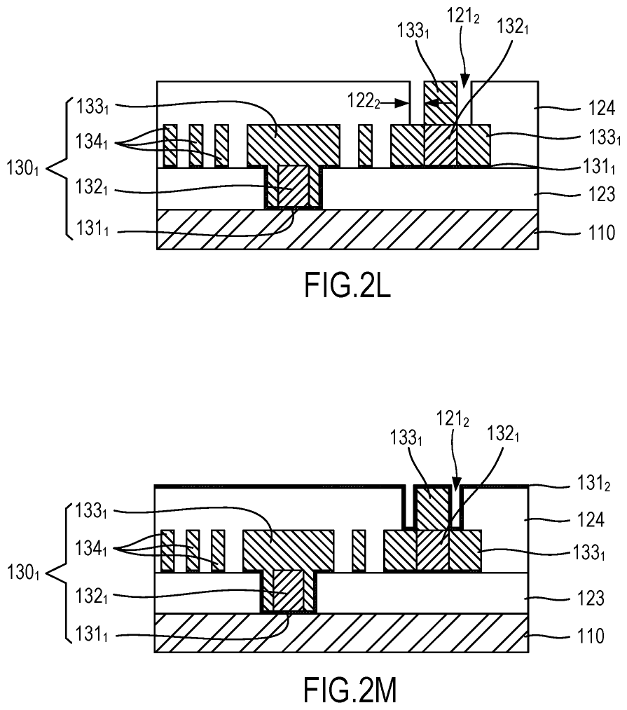

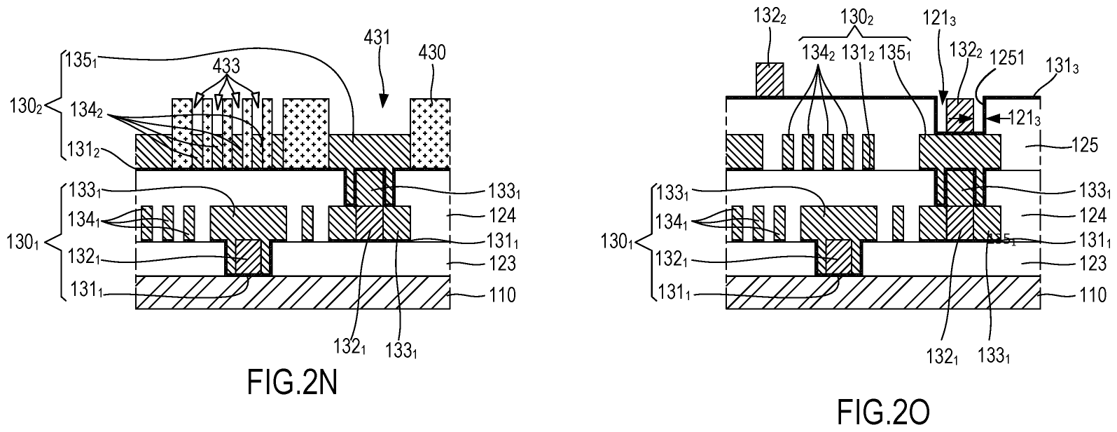

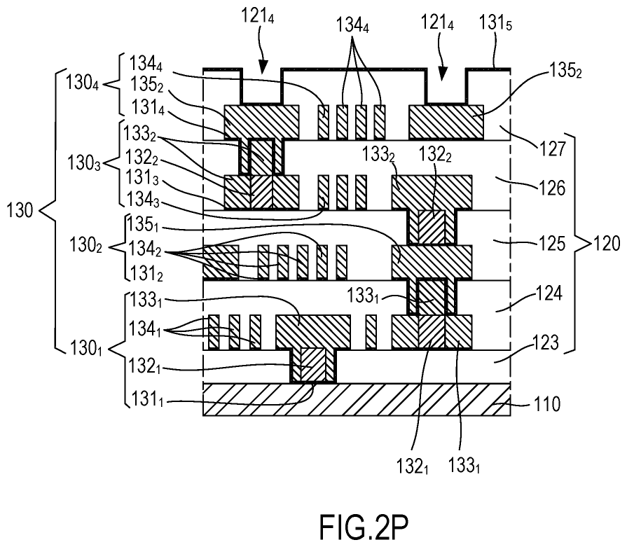

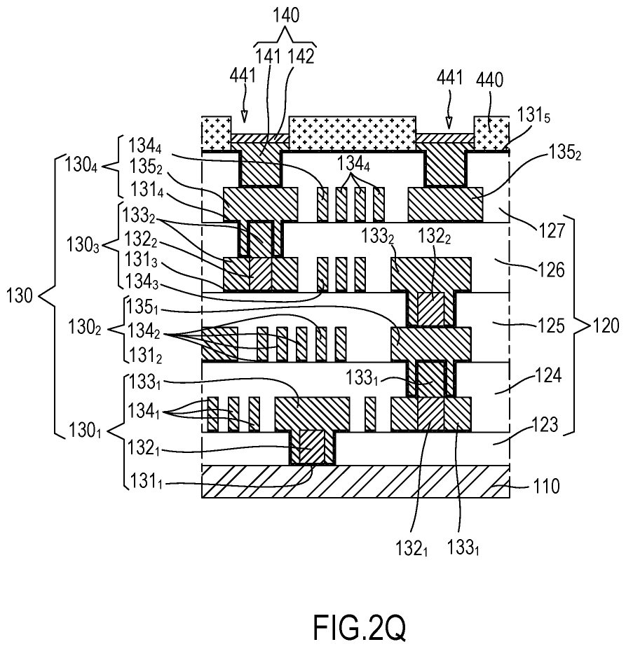

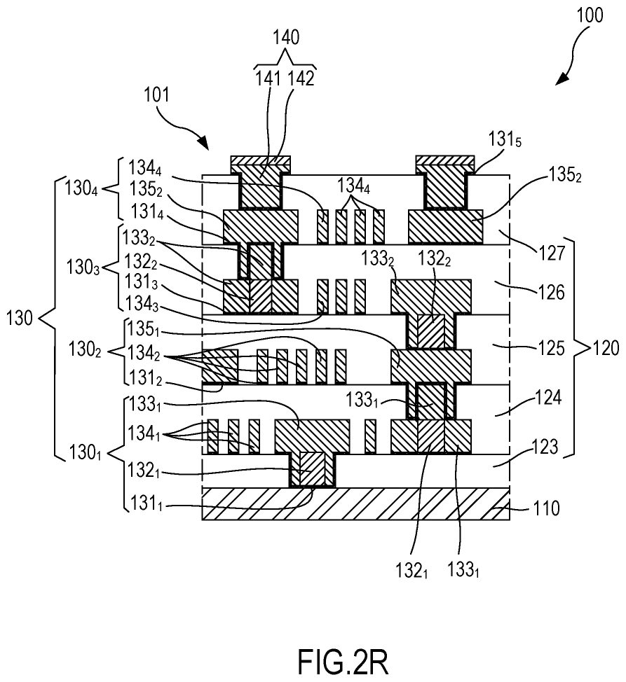

FIGS. 2A to 2R show cross-sectional views and top views of an example method for manufacturing an example electronic component, such as electronic component 100 in FIG. 1. Top views can accompany cross-sectional views in some illustrations.

FIG. 2A shows a cross-sectional view of electronic component 100 at an early stage of manufacture. In the example shown in FIG. 2A, dielectric layer 123 of dielectric structure 120 can be provided on substrate 110. In some examples, substrate 110 can comprise or be referred to as a wafer, a reconstituted wafer, or a removable carrier. For example, substrate 110 can be a wafer having a plurality of semiconductor die separated by saw streets and can be used to manufacture electronic devices comprising Wafer Level Packages (WLPs) or Wafer Level Chip Size Packages (WLCSPs). In some examples, substrate 110 can be a reconstituted wafer comprising a plurality of known good semiconductor die aggregated and reconstituted (e.g., encapsulated) to form substrate 110 (e.g., encapsulant can be located between adjacent semiconductor die). The reconstituted wafer can be used to manufacture electronic devices comprising, for example, Wafer Level Fan Out (WLFO) devices. In some examples, substrate 110 can comprise a removable (or temporary) carrier and can be used to manufacture electronic devices comprising redistribution layer (RDL) substrates (e.g., redistribution structure 101) on which electronic components (e.g., semiconductor die, passive devices, or other electronic packages) are coupled. The removable carrier can be formed of, for example, silicon, glass, ceramic, or metal, and can be removed from the RDL substrate after the electronic components have been attached to the RDL substrate. The height of substrate 110 can range from about 200 μm to about 1000 μm.

Dielectric layer 123 can be formed by providing dielectric material on substrate 110. In some examples, the dielectric material can comprise one or more layers of photo imageable organic passivation material such as, polyimide (PI), benzocyclobutene (BCB), or polybenzoxazole (PBO). In some examples, dielectric layer 123 can comprise phenolic resin or Ajinomoto Buildup Film (ABF). In some examples, the dielectric material can comprise one or more layers of inorganic dielectric material, such as for example silicon oxide (SiO2), silicon nitride (Si3N4), or silicon oxynitride (SiON). Dielectric layer 123 can be provided by spin coating, spray coating, dip coating, rod coating, printing, oxidation, PVD, CVD, MOCVD, ALD, LPCVD, PECVD, or attached as a pre-formed film on substrate 110. The height of dielectric layer 123 can range from about 1 μm to about 100 μm.

FIG. 2B and FIG. 2B-1 show a cross-sectional view and a top-down view, respectively, of electronic component 100 at a later stage of manufacture. The cross-section of FIG. 2B is taken along line 2B-2B in FIG. 2B-1. In the example shown in FIGS. 2B and 2B-1, dielectric layer 123 can be patterned to provide one or more via(s) (or opening(s)) 121 in dielectric layer 123. An inner wall 1231 of dielectric layer 123 can define via 121. Dielectric layer 123 can be patterned using, for example, a photolithography and/or etching process. The diameter or width of each via 121 can range from about 5 μm to about 90 μm. In some examples, via 121 can have a diameter or width greater than a width of a via filling limit, which can be about 10 μm. In some examples, the via filling limit can range from about 0.1 μm to about 30 μm. As used herein, a via filling limit can be a maximum width of a via that can be filled with conductive material without creating a dimple on a top side of the conductive material. In some examples, via 121 can be substantially circular when viewed from above (e.g., can have a circular cross-section in an x-y (or horizontal) plane). In examples where substrate 110 comprises a wafer or a reconstituted wafer, the location of via(s) 121 can corresponding to input/output (i/o) terminal(s) of the semiconductor die (e.g., via 121 can vertically overlap and expose an i/o terminal of the semiconductor die). In some examples, the i/o terminal can comprise or be referred to as a pad, land, stud bump, interconnect, or Under Bump Metallization (UBM).

FIG. 2C shows a cross-sectional view of electronic component 100 at a later stage of manufacture. In the example shown in FIG. 2C, seed layer 131₁ can be provided on dielectric layer 123 and in via 121. Seed layer 131₁ can also be provided on the portion of substrate 110 that is exposed through via 121. In some examples, seed layer 131₁ can comprise Copper (Cu), Titanium/Copper (Ti/Cu), Thallium/Copper (Ta/Cu), Titanium Tungsten/Copper (TiW/Cu), or Titanium/Titanium Nitride/Copper (Ti/TiN/Cu). For example, a barrier metal such as Ti, Ta, TiW, or TiN can first be provided on dielectric layer 123 and in via 121, and then Cu can be provided on the barrier metal. The barrier metal tends to reduce or prevent Cu from diffusing into dielectric layer 123. The barrier metal comprising Ti, Ta, TiW, or TiN can be provided through Atomic Layer Deposition (ALD), Physical Vapor Deposition (PVD), Chemical Vapor Deposition (CVD), Low Pressure Chemical Vapor Deposition (LPCVD), or Plasma Enhanced Chemical Vapor Deposition (PECVD). The Cu portion of seed layer 131₁ can be provided through PVD, ALD, CVD, LPCVD, or PECVD. The thickness or height of seed layer 131₁ can range from about 0.05 μm to about 1 μm. Seed layer 131₁ can provide a current supply path for electroplating conductive structures over substrate 110 and dielectric 123, as further described below.

FIG. 2D shows a cross-sectional view of electronic component 100 at a later stage of manufacture. In the example shown in FIG. 2D, photoresist 410 can be provided on seed layer 131₁ by spin coating, spray coating, dip coating, rod coating, or, in some examples, by laminating a dry film. Photoresist 410 can be patterned to provide vias 411 and 412 in photoresist 410. For example, a mask having a pattern corresponding to the locations of vias 411 and 412 can be positioned on photoresist 410. The mask can then be exposed to ultraviolet rays, which transfers the pattern to photoresist 410. The portion of photoresist 410 that includes the transferred pattern, or, in some examples, the portion that does not include the transferred pattern is then developed and cured, leaving vias 411 and 412 patterned in photoresist 410. In some examples, vias 411 and 412 can be substantially circular when viewed from the top (e.g., can have a circular cross-section in a horizontal plane).

In accordance with various examples, a diameter or width of via 411 can be less than the diameter or width of via 121. For example, via 411 can be provided inside of, or within, via 121 such that photoresist 410 and via 411 extend into via 121 and a portion of photoresist 410 overlaps sidewall 1231 in the lateral (or horizontal) direction. The portion of photoresist 410 that is located inside via 121 can have an annular geometry. Inner wall 4111 of photoresist 410 can define via 411. In some examples, via 412 can be provided on or above dielectric layer 123. Inner wall 4121 of photoresist 410 can define via 412. The lateral thickness of photoresist 410, as measured between the inner wall 4111 of photoresist 410 and seed layer 131₁, can be less than a maximum via fill width. In some examples, the maximum via fill width can be about 8 μm, about 9 μm, about 10 μm, about 11 μm, or about 12 μm.

In some examples, the depth of via 411 can be greater than the depth of via 412 (i.e., the height or vertical thickness of inner wall 4111 of photoresist 410 can be greater than the height or vertical thickness, respectively, of inner wall 4121 of photoresist 410). In some examples, the diameter or width of via 411 can be similar to or the same as the diameter or width of via 412. In some examples, the diameter or width of vias 411 and 412 can be adjusted based on the diameter of via 121. For example, diameter of via 411 can range from about 5 μm to about 20 μm less than the diameter of via 121.

FIG. 2E and FIG. 2E-1 show a cross-sectional view and a top-down view, respectively, of electronic component 100 at a later stage of manufacture. The cross-section of FIG. 2E is taken along line 2E-2E in FIG. 2E-1. In the example shown in FIGS. 2E and 2E-1, one or more conductor(s) 132₁ can be provided over seed layer 131₁. Conductor 132₁ can be provided on seed layer 131₁ in via 411. The annular portion of photoresist 410 that is disposed in via 121 can surround the conductor 132₁ located in via 411. In some examples, conductor 132₁ located in via 411 can be coupled to an i/o terminal of substrate 110. In some examples, a conductor 132₁ can also be provided on seed layer 131₁ in via 412. The height of the top side of the conductor 132₁ in via 412 can be higher than the height of the top side of the conductor 132₁ in via 411.

In some examples, conductors 132₁ in vias 411 and 412 can be circular when viewed from above (i.e., can have a circular cross-section in a horizontal plane). In some examples, conductor(s) 132₁ can be provided by PVD, CVD, electrolytic plating, electroless plating process, or any other suitable metal deposition process. conductor(s) 132₁ can comprise one or more layers of Cu, nickel (Ni), gold (Au), silver (Ag), aluminum (Al), titanium (Ti), titanium tungsten (TiW), or other suitable electrically conductive material. The width or diameter of conductor 132₁ can range from about 1 μm to about 200 μm.

FIG. 2F shows a cross-sectional view of electronic component 100 at a later stage of manufacture. In the example shown in FIG. 2F, photoresist 410 is removed. In some examples, photoresist 410 can be removed by a liquid resist stripper. In some examples, the liquid resist stripper can comprise monoethanolamine and 2-butoxy ethanol. In some examples, photoresist 410 can be removed by an oxygen-containing plasma. In some examples, photoresist 410 can be removed by a solvent such as, for example, 1-methyl-2-pyrrolidone (NMP). In some examples, once photoresist 410 is dissolved by a solvent, the solvent can be removed by heating to about 80° C. to leave seed layer 131₁ devoid of residue from photoresist 410.

In response to removal of photoresist 410, the top side and lateral sides of conductors 132₁ can be exposed. In some examples, lateral sides of the conductor 132₁ in via 121 can be spaced apart from inner wall 1231 of via 121 of dielectric layer 123 by gap 122₁ (also referred to herein as a space or void). Gap 122₁ can be defined between the lateral side of conductor 132₁ disposed in via 121 and the inner wall 1231 of dielectric layer 132 that defines via 121. Gap 122₁ can range from about 5 μm to about 20 μm. In some examples, gap 122₁ is less than about 8 μm, about 9 μm, about 10 μm, about 11 μm, or about 12 μm. In some examples, gap 122₁ is selected based on a width of a via filling limit. As described in further detail below, gap 122₁ can be filled with conductor 133₁ (FIG. 2H), and conductor 133₁ can have a substantially flat top side.

In some examples, the top side of the conductor 132₁ in via 121 can be coplanar with the top side of seed layer 131₁ located on dielectric layer 123. In some examples, the height of the conductor 132₁ in via 121 can be similar to or the same as the height of the inner wall 1231 of dielectric layer 123. Conductors 132₁ can be provided on a portion of seed layer 131₁ located in via 121 and on a portion seed layer 131₁ located over dielectric layer 123. As described above, the conductor 132₁ located on dielectric layer 123 can be located a greater distance above substrate 110 than the conductor 132₁ in via 121. In some examples, the height of the conductor 132₁ located on dielectric layer 123 can be similar to or the same as the height of the conductor 132₁ located in via 121.

FIG. 2G shows a cross-sectional view of electronic component 100 at a later stage of manufacture. In the example shown in FIG. 2G, patterned photoresist 420 can be provided over seed layer 131₁. Photoresist 420 can be patterned in a manner similar to or the same as photoresist 410 described above. In some examples, vias 421 and 422 and RDL vias 423 can be defined by inner sides of photoresist 420. In some examples, vias 421 and 422 can be circular when viewed from the top (e.g., vias 421 and 422 can have a circular cross-section in a horizontal plane). In some examples, RDL vias 423 can be linear when viewed from the top (e.g., RDL vias 423 can have a rectangular cross-section in a horizontal plane).

In accordance with various examples, via 421 can have a greater diameter than the diameter of conductor 132 and the diameter of via 121. In some examples, via 422 can have a greater diameter than the diameter of conductor 132 (i.e., a diameter greater than the diameter of via 412 in in FIG. 2E). The diameter or width of vias 421 and 422 can range from about 11 μm to about 150 μm. In some examples, conductors 132 and a portion of seed layer 131₁ can be exposed through vias 421 and 422. In some examples, RDL vias 423 can be provided over dielectric layer 123. The width of RDL vias 423 can be less than the widths of vias 421 and 422. The width of RDL vias 423 can range from about 0.1 μm to about 100 μm.

FIG. 2H shows a cross-sectional view of electronic component 100 at a later stage of manufacture. In the example shown in FIG. 2H, conductors 133₁ and traces 134₁ can be provided over seed layer 131₁ and conductors 132₁. In some examples, an additive or a plating accelerant can be deposited in gap 122₁ to increase a plating rate of the portion of conductor 133₁ disposed in via 121. An example accelerant can include Bis (3-sulfopropyl) Disulfide (SPS). Gap 122₁ may be filled with a curvature enhanced accelerator coverage (CEAC) to leave a substantially flat top side. Conductors 133₁ and traces 134 can be provided by PVD, CVD, electrolytic plating, electroless plating process, or any other suitable metal deposition process. Conductors 133₁ and traces 134₁ can comprise one or more layers of Cu, Ni, Au, Ag, Al, Ti, TiW, or other suitable electrically conductive material.

The conductor 133₁ in vias 421 and 121 can surround, cover, or contact the conductor 132₁ located in via 121. Conductor 133₁ can extend into gap 122₁, between a lateral side of conductor 132₁ and inner side 1231 of dielectric layer 123.

In some examples, conductor 133₁ in via 421 can have a substantially flat top side. The top side of conductor 133₁ in via 421 can lack dimples as a result of gap 122₁ having a width less than a via filling limit. In some examples, the via filling limit can range from about 0.1 μm to about 30 μm. If a width of a via exceeds the via filling limit, a dimple can be formed on the top side of the conductor that fills the via. By avoiding formation of dimples on the top side of conductor 133₁, narrow width and/or fine pitch RDL traces (e.g., traces having a width of 0.5 μm to about 2 μm and a pitch of about 1 μm to 4 μm) can be provided above conductor 133₁. Additionally, the risk of RDL traces above conductor 133₁ collapsing can be minimized or eliminated due to the planarity of (i.e., lack of dimples on) the top side of conductor 133₁, which can increase the likelihood of the fine RDL traces passing an Automatic Optics Inspection (AOI). The height of conductor 133₁ can range from about 1 μm to about 20 μm from the top of dielectric layer 123. In some examples, conductor 133₁ can be coupled to an input/output terminal of substrate 110 together with conductor 132₁. Conductor 133₁ can also be coupled to at least one trace 134₁, as shown in FIG. 2J-1.

The conductor 133₁ provided in via 422 can surround, cover, or contact the conductor 132₁ in via 422. In some examples, conductor 133₁ can cover the lateral side and top side of the conductor 132₁ in via 422. In some examples, a portion of the conductor 133₁ on the top side of conductor 132₁ can protrude above conductor 132₁. In some examples, a protrusion portion of the conductor 133₁ in via 422 can be higher than the top side of the conductor 133₁ in via 421. In some examples, conductors 132 and 133 in via 422 are electrically coupled to one or more trace(s) 134 on the same layer (e.g., to one or more trace(s) 134₁ on dielectric layer 123), to a conductor on another layer (e.g., to conductor 135₁ in FIG. 2N), or to one or more trace(s) 134 on another layer (e.g., to one or more trace(s) 134₂ in FIG. 2N). In some examples, the combined height (e.g., above seed layer 131₁) of conductors 132₁ and 133₁ in via 421 can be similar to the same as the combined height (e.g., above seed layer 131₁) of conductors 132₁ and 133₁ in via 422.

FIG. 2I shows a cross-sectional view of electronic component 100 at a later stage of manufacture. In the example shown in FIG. 2I, photoresist 420 can be removed by, for example, a liquid resist stripper. In some examples, the process of removing photoresist 420 can be similar to or the same as the process for removing photoresist 410, as described above. In some examples, seed layer 131₁, conductor 132₁, and conductor 133₁, provided on substrate 110 can be collectively referred to as conductive pattern 130₁. The height (i.e., in the direction away from substrate 110) of conductive pattern 130₁ can range from about 1 μm to about 200 μm. In some examples, conductive pattern 130₁ can further comprise traces 134₁ provided on dielectric layer 123. In some examples, conductive pattern 130₁ can further comprise conductor 132₁ and conductor 133₁ provided on dielectric layer 123.

In some examples, conductive pattern 130₁ can comprise one or more conductive components defining signal distribution elements such as traces, vias, pads, conductive paths, or UBM. Conductive structure 130 can form conductive paths horizontally and vertically through dielectric structure 120. In some examples, conductor 132₁ and conductor 133₁ can be referred to as a via or pad. In some examples, trace 134₁ can comprise or be referred to as a RDL or RDL pattern. In some examples, the width of each conductor 132₁ and conductor 133₁ is greater than the width of each trace 134₁.

FIG. 2J and FIG. 2J-1 show a cross-sectional view and a top-down view, respectively, of electronic component 100 at a later stage of manufacture. The cross-section of FIG. 2J is taken along line 2J-2J in FIG. 2J-1. In the example shown in FIGS. 2J and 2J-1, a portion of seed layer 131₁ can be removed. In some examples, conductors 133₁ and traces 134₁ can be used as masks, such that the portion of seed layer 131₁ that is uncovered by conductors 133₁ and traces 134₁ is removed. In some examples, the exposed portion of seed layer 131₁ can be removed by an etching process. In some examples, a Cu portion of seed layer 131₁ can be etched first, and a Ti or TiW portion of seed layer 131₁ can then be etched after removal of the Cu portion. In response to removal of seed layer 131₁, the top side of dielectric layer 123 (i.e., the portion of dielectric layer 132 that is outside the footprints of conductors 133₁ and traces 134₁) can be exposed. The ends of seed layer 131₁ can also be exposed and can be coplanar with conductors 133₁ or traces 134₁.

FIG. 2K shows a cross-sectional view of electronic component 100 at a later stage of manufacture. In the example shown in FIG. 2K, dielectric layer 124 of dielectric structure 120 can be provided over the top side of the dielectric layer 123 and over conductive pattern 130₁. The elements, features, materials, and formation processes of dielectric layer 124 can be similar to or the same as the elements, features, materials, and formation processes described above for dielectric structure 123, and will thus not be repeated herein. In some examples, the top side of conductor 133₁ can be exposed at the top side of dielectric layer 124. In some examples, the top side of conductor 133₁ can be coplanar with the top side of dielectric layer 124.

FIG. 2L shows a cross-sectional view of electronic component 100 at a later stage of manufacture. In the example shown in FIG. 2L, dielectric layer 124 can be patterned to provide via 121₂ in dielectric layer 124. The elements, features, materials, and steps of the patterning process of dielectric layer 124 can be similar to or the same as the patterning process described above with respect to dielectric layer 123 and will thus not be repeated herein. Via 121₂ can be defined by inner wall 124₁ of dielectric layer 124. The diameter or width of via 121₂ can range from about 10 μm to about 100 μm.

In accordance with various examples, the top side and lateral sides of conductor 133₁ can be exposed through via 121₂. An inner wall 124₁ of dielectric layer 124 defines via 121₂. In some examples, a portion of conductor 132₁ can also be exposed through via 121₂. In some examples, gap 122₂ can be defined between the lateral side of conductor 133₁ and inner wall 124₁ of dielectric layer 124. In some examples, gap 122₂ can range from about 5 μm to about 20 μm. In some examples, gap 122₂ is less than the via filling limit, as previously described.

FIG. 2M shows a cross-sectional view of electronic component 100 at a later stage of manufacture. In the example shown in FIG. 2M, seed layer 131₂ can be provided on dielectric layer 124 and in via 121₂. In some examples, seed layer 131₂ can be provided on conductor 133₁. In some examples, seed layer 131₂ can be provided on the portion of conductor 133₁ that is located on dielectric layer 123 and on the portion of conductor 133₁ that is located on conductor 132₁. In some examples, seed layer 131₂ can also be provided on the inner wall 124₁ of dielectric layer 124. The elements, features, materials, and formation processes of seed layer 131₂ can be similar to or the same as the elements, features, materials, and formation processes described above for seed layer 131₁, and will thus not be repeated herein.

FIG. 2N shows a cross-sectional view of electronic component 100 at a later stage of manufacture. In the example shown in FIG. 2N, conductor 135₁ and traces 134₂ can be provided on seed layer 131₂. The elements, features, materials, and formation processes of conductor 135₁ and traces 134₂ can be similar to or the same as the elements, features, materials, and formation processes described above for conductor 133 and traces 134₁ and will thus not be repeated herein. Conductor 135₁ can be provided on seed layer 131₂ in via 431 of photoresist 430. Conductor 135₁ can extend into gap 122₂ and into via 121₂. In some examples, conductor 135₁ can have a dimple-free top side due to gap 122₂ filling with a substantially flat top side. Gap 122₂ inside via 421 can have a width less than the via filling limit to avoid dimples in the top side of conductor 135₁. In some examples, the top side of conductor 135₁ can be substantially flat or planar. The height of conductor 135₁ above seed layer 131₂ can range from about 1 μm to about 20 μm, and the width can range from about 1 μm to about 200 μm. Conductor 135₁ can be coupled to conductor 133₁. Conductor 135₁ can also be coupled to one or more trace(s) 134₁ or one or more trace(s) 134₂.

In some examples, traces 134₂ can be provided in trace vias 433. Traces 134₂ can be provided over dielectric layer 124 of dielectric structure 120 and can be located above conductive pattern 130₁. The top side of dielectric layer 124 can be substantially flat due to being formed on the substantially flat top side of conductive pattern 130₁ (e.g., the substantially flat top side of conductor 133₁). The substantially flat top side of dielectric layer 124, which results from the substantially flat top side of conductive pattern 130₁) tends to reduce a likelihood of trace vias 433 collapsing (or tilting), which can result in misshaping of traces 134₂. Maintaining the proper shape of trace vias 433 results in traces 134₂ each comprising vertical sidewalls that are substantially parallel to one another in the region above conductor 133₁. The height of each trace 134₂ can range from about 1 μm to about 20 μm, and the width can range from about 0.5 μm to about 200 μm. In some examples, seed layer 131₂, conductor 135₁, and traces 134₂ can be referred to as conductive pattern 130₂.

FIG. 2O shows a cross-sectional view of electronic component 100 at a later stage of manufacture. In the example shown in FIG. 2O, dielectric layer 125 of dielectric structure 120, seed layer 131₃, and one or more conductor(s) 132₂ can be provided over dielectric layer 124 and conductive pattern 130₂. In accordance with various examples, a conductor 132₂ is provided in via 121₃ and on conductor 135₁. The structure shown in FIG. 2O can be provided using a process similar to or the same as process described above with reference to FIGS. 2A-2F. The elements, features, materials, and formation processes of dielectric layer 125 can be similar to or the same as the elements, features, materials, and formation processes described above for dielectric layer 123. In some examples, via 121₃ can be provided in a portion of dielectric layer 125 that is disposed over and around conductor 135₁ using a process similar to or the same as the process shown in FIG. 2B. Seed layer 131₃ can be provided in via 121₃ and on dielectric layer 125. Seed layer 131₃ can be provided on the exposed region of conductor 135₁. Conductor 132 can be provided on a portion of seed layer 131 that vertically overlaps conductor 135₁ using a process similar to or the same as the processes shown in FIGS. 2D, 2E, and 2F. In accordance with various embodiments, one or more conductor(s) 132₂ can be provided on seed layer 131 over a top side of dielectric layer 125 using a process similar to or the same as the processes shown in FIGS. 2D, 2E, and 2F.

FIG. 2P shows a cross-sectional view of electronic component 100 at a later stage of manufacture. In the example shown in FIG. 2P, conductors 133₂, traces 134₃, and dielectric layer 126 can be provided by repeating the steps and processes described above with reference to FIGS. 2G, 2H, 2I, and 2K. In some examples, seed layer 131₃, conductors 132₂, traces 134₂, and conductors 133₂ can be referred to as conductive pattern 130₃. In accordance with various examples, seed layer 131₄, conductor(s) 135₂, and traces 134₄ can be provided over conductive pattern 130₃ and dielectric layer 126 by repeating the steps and processes described above with reference to seed layer 131₂, conductor 135₁, and traces 134₂ in FIGS. 2L, 2M, 2N and 2O. In some examples, seed layer 131₄, conductor(s) 135₂, and traces 134₄ can be referred to as conductive pattern 130₄.

Dielectric layer 127 of dielectric structure 120 can be provided over conductive pattern 130₄ and conductive layer 126. The elements, features, materials, and formation processes of dielectric layer 127 can be similar to or the same as the elements, features, materials, and formation processes described above for dielectric layer 123. In various examples, conductive structure 130 can include conductive patterns 130₁ 130₂ 130₃, and 130₄, and dielectric structure 120 can include dielectric layers 123, 124, 125, 126, and 127. However, it is contemplated and understood that dielectric structure 120 and conductive structure 130 can each include any number of dielectric layer and conductive patterns, respectively. In this regard, dielectric structure 120 can include more or fewer dielectric layers and conductive structure 130 can include more or fewer conductive patterns.

As further shown in FIG. 2P, via(s) 121₄ can be provided in dielectric layer 127. Vias 121₄ can be located over and expose, at least, a portion of conductors 135₂. Seed layer 131₅ can be provided on dielectric layer 127 and on conductor 135₂ in via 121₄. The elements, features, materials, and formation processes of seed layer 131₅ can be similar to or the same as the elements, features, materials, and formation processes described above for seed layer 131₁.

FIG. 2Q shows a cross-sectional view of electronic component 100 at a later stage of manufacture. In the examples shown in FIG. 2Q, component interconnects 140 can be provided conductive structure 130 (e.g., on the top side of conductors 135₂). In some examples, component interconnect 140 can comprise contact pad 141 and terminal tip 142. Contact pad 141 can be provided on seed layer 131₅. In some examples, contact pad 141 can be provided in via 121₄ (FIG. 2P) and via 441 defined by photoresist 440. In some examples, contact pad 141 can have a substantially flat top side. The height of contact pad 141 can range from about 1 μm to about 500 μm. In some examples, terminal tip 142 can be electrolytically deposited on contact pad 141. Terminal tip 142 can also be provided by depositing tip in via 121₄ in photoresist 440. In some examples, terminal tip 142 can comprise Sn (tin), Ag (silver), Pb (lead), Cu (copper), Sn—Pb, Sn₃₇—Pb, Sn₉₅—Pb, Sn—Pb—Ag, Sn—Cu, Sn—Ag, Sn—Au, Sn—Bi, or Sn—Ag—Cu. The width of terminal tip 142 can range from about 0.001 mm (millimeter) to about 10 mm. Terminal tip 142 can serve to couple electronic component 100 to an external device.

FIG. 2R shows a cross-sectional view of electronic component 100 at a later stage of manufacture. In the example shown in FIG. 2R, photoresist 440 (FIG. 2Q) and the portions of seed layer 131₅ that are not covered by component interconnects 140 can be removed, as previously described. The top side and lateral sides of component interconnect 140, comprising contact pad 141 and terminal tip 142, can be exposed. In some examples, terminal tip 142 of component interconnect 140 can be made rounded by a reflow process or laser assisted process. In some examples, the processes for rounding terminal tip 142 can be performed using temperatures of about 150° C. to about 250° C.

In accordance with various examples, individual electronic components 100 can be provided by a singulation process. In some examples, the singulation process can include sawing or cutting through substrate 110, dielectric structure 120, or conductive structure 130. In some examples, in response to singulation, lateral sides of substrate 110, dielectric structure 120, or conductive structure 130 can be coplanar.

In examples where substrate 110 is a removable carrier, substrate 110 can be separated from redistribution structure 101. In some examples, a wafer support system can be attached to redistribution structure 101 (e.g., over the top side of dielectric layer 127 and component interconnects 140), and substrate 110 can then be removed from the opposite side of redistribution structure 101. In some examples, a temporary bond layer (e.g., a temporary bonding film, a temporary bonding tape, or a temporary adhesive coating) can be interposed between redistribution structure 101 and substrate 110. For example, the temporary bond layer can be a heat release tape (film) or an optical release tape (film), in which the adhesive strength is weakened or removed by heat or light, respectively. The temporary bond layer can allow redistribution structure 101 to be separated from substrate 10. In some examples, a force (e.g., chemical or physical) can also be used to overcome the adhesive strength of the temporary bond layer. In some examples, substrate 110 can be removed by mechanical grinding and chemical etching.

In response to removing or separating substrate 110, the bottom side of redistribution structure 101 can be exposed (e.g., the bottom sides of dielectric layer 123 and seed layer 131₁ or conductors 132₁ and 133₁ can be exposed). In some examples, the bottom side of seed layer 131₁ and the bottom side of dielectric layer 123 can be coplanar. In some examples, the exposed (or bottom) portions of conductive pattern 130₁ can comprise or be referred to as internal terminals.

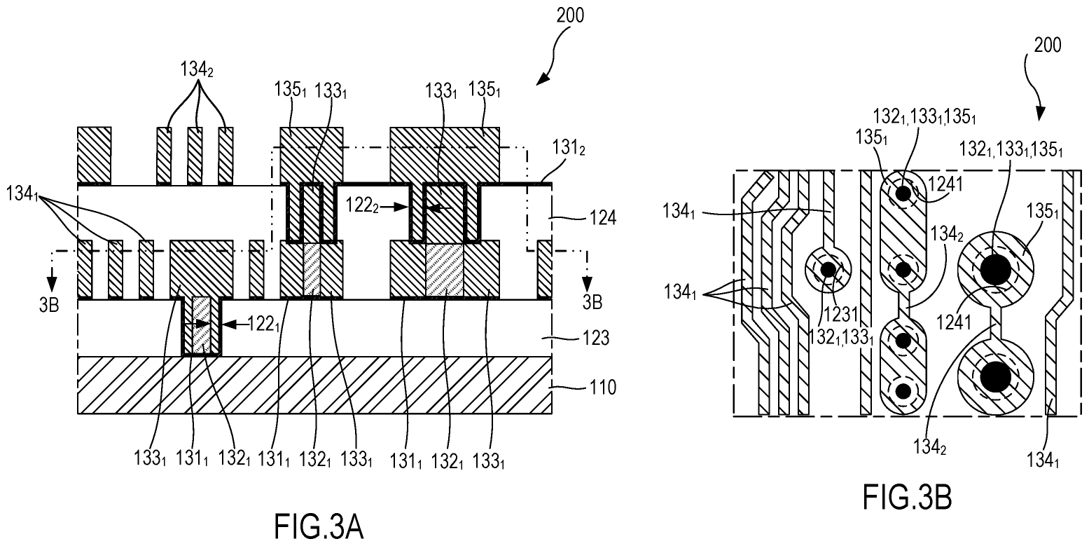

FIGS. 3A and 3B show a cross-sectional view and a top view, respectively, of an example electronic component 200. The top view of FIG. 3B is taken along line 3B-3B in FIG. 3A. In the example shown in FIGS. 3A and 3B, conductors 132₁, conductors 133₁, and conductors 135₁ can vary in diameter (or width) at different locations. In some examples, a relatively small diameter of conductor 132₁, conductor 133₁, or conductor 135₁ can range from about 1 μm to about 95 μm. In some examples, a relatively large diameter of conductor 132₁, conductor 133₁, or conductor 135₁ can range from about 10 μm to about 100 μm. However, regardless of whether the diameter of conductor 132₁ or conductor 133₁ is relatively small or large, each of the gap between the lateral side of the conductor 132₁ and inner wall 1231 of dielectric layer 123 (e.g., gap 122₁) and the gap between the lateral wall of conductor 133₁ and inner wall 124₁ of dielectric layer 124 (e.g., gap 122₂) can be less than the via filling limit. Maintaining a width of gaps 122₁, 122₂ less than the via filling limit tends to prevent formation of a dimple in the top side of the conductor 133₁ provided on conductor 132₁ or in the top side of the conductor 135₁ provided on conductor 133₁.

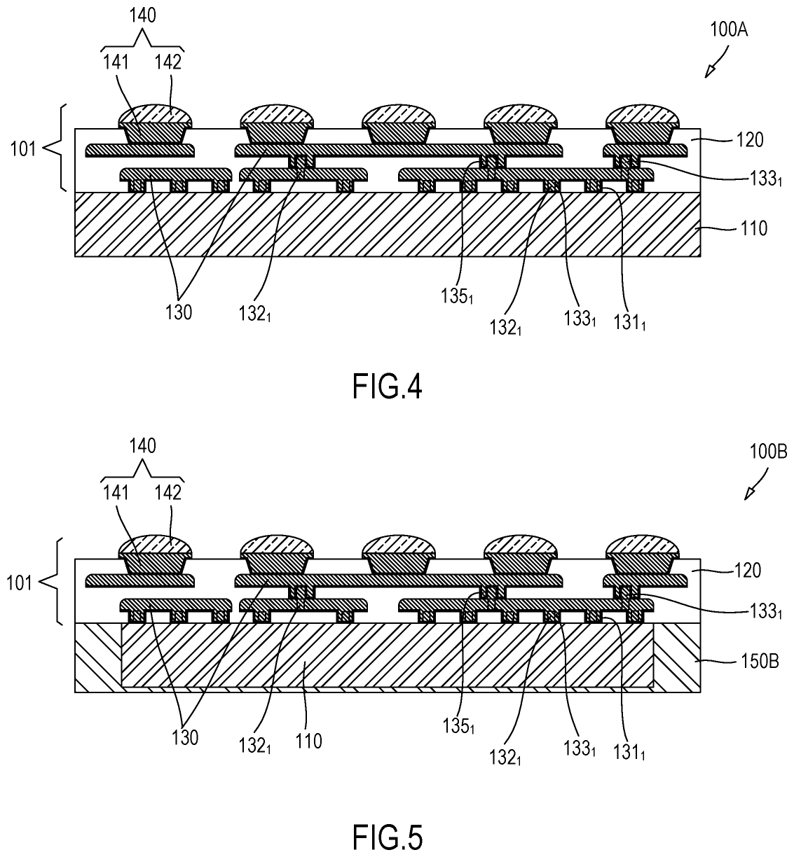

FIG. 4 shows a cross-sectional view of an example electronic device 100A. In the example shown in FIG. 4, electronic device 100A can comprise substrate 110 and redistribution structure 101. Redistribution structure 101 includes dielectric structure 120 and conductive structure 130, as previously described with reference to FIGS. 2A-2R. In some examples, redistribution structure 101 can further include component interconnects 140. In accordance with various examples, electronic device 100A can be manufactured using a process similar to the processes shown in FIGS. 2A-2R. In some examples, redistribution structure 101 of electronic device 100A can comprise dimple-less vias provided using processes similar to or the same as those shown in FIGS. 2A-2R. In some examples, electronic device 100A can comprise or be referred to as WLP or WLCSP.

In some examples, substrate 110 of electronic device 100A can comprise or be referred to as a semiconductor die, a semiconductor chip, or a semiconductor package. In some examples, the die or chip can comprise an integrated circuit die singulated from a semiconductor wafer having multiple die. In some examples, substrate 110 can comprise a DSP (digital signal processor), a network processor, a power management unit, an audio processor, a RF (radio-frequency) circuit, a wireless baseband SoC (system-on-chip) processor, a sensor, or an ASIC (application specific integrated circuit). Substrate 110 can perform calculation and control processing, store data, or remove noise from electrical signals. The bottom sides of conductors 132₁ and 133₁ can provide internal terminals of redistribution structure 101 (i.e., terminals opposite component interconnects 140), and can be coupled to I/O terminals (or contact pads) of substrate 110.

FIG. 5 shows a cross-sectional view of an example electronic device 100B. In the example shown in FIG. 5, electronic device 100B can comprise substrate 110, redistribution structure 101, and encapsulant 150B. Redistribution structure 101 includes dielectric structure 120 and conductive structure 130, as previously described with reference to FIGS. 2A-2R. In some examples, redistribution structure 101 can further include component interconnects 140. Electronic device 100B shown in FIG. 5 can be similar to electronic device 100A shown in FIG. 4 with electronic device 1001B comprising encapsulant 150B. In some examples, electronic device 100B can be fabricated by a process similar to or the same as processes shown in FIGS. 2A-2R with the addition of substrate 110 being encapsulated with encapsulant 150B.

In some examples, encapsulant 150B can comprise an epoxy resin or a phenol resin, carbon black, or a silica filler. In some examples, encapsulant 150B can comprise or be referred to as a mold compound, a resin, a sealant, a filler-reinforced polymer, or an organic body. In some examples, encapsulant 150B can cover or contact a bottom side or lateral sides of substrate 110. In some examples, a bottom side of encapsulant 150B can be lower than the bottom side of substrate 110. In some examples, the bottom side of encapsulant 150B and the bottom side of substrate 110 can be coplanar such that the bottom side of substrate 110 can be exposed from the bottom side of encapsulant 150B. In some examples, the top side of substrate 110 and the top side of encapsulant 150B can be coplanar.

Encapsulant 150B can be provided by transfer molding, compression molding, liquid encapsulant molding, vacuum lamination, paste printing, film assist molding or any other suitable deposition process. The height of encapsulant 150B can range from about 10 μm to about 2000 μm. Encapsulant 150B can protect substrate 110 from the external environment or environmental exposure and can dissipate heat from substrate 110.

In some examples, redistribution structure 101, including conductive structure 130 and dielectric structure 120, can be provided on the top side of encapsulant 150B and on the top side of substrate 110. In accordance with various examples, the processes described above with reference to FIGS. 2A-2R can be implemented to provide redistribution structure 101 over substrate 110 and encapsulant 150B. In some examples, redistribution structure 101 can further include component interconnects 140 provided over the top side of conductive structure 130. In some examples, one or more of the component interconnects 140 or portions of conductive structure 130 can be located vertically over the top side of encapsulant 150B. In some examples, dielectric structure 120 (e.g., dielectric layer 123 in FIG. 2A) can contact encapsulant 150B. In some examples, electronic device 1001B can comprise or be referred to as a WLFO. The bottom sides of conductors 132₁ and 133₁ can provide internal terminals of redistribution structure 101 (i.e., terminals opposite component interconnects 140), and can be coupled to I/O terminals (or contact pads) of substrate 110.

In accordance with various examples, individual electronic devices 1001B can be provided by a singulation process. In some examples, singulation can include sawing or cutting through encapsulant 150B and redistribution structure 101. In some examples, lateral sides of encapsulant 150B, dielectric structure 120, or conductive structure 130 can be coplanar.

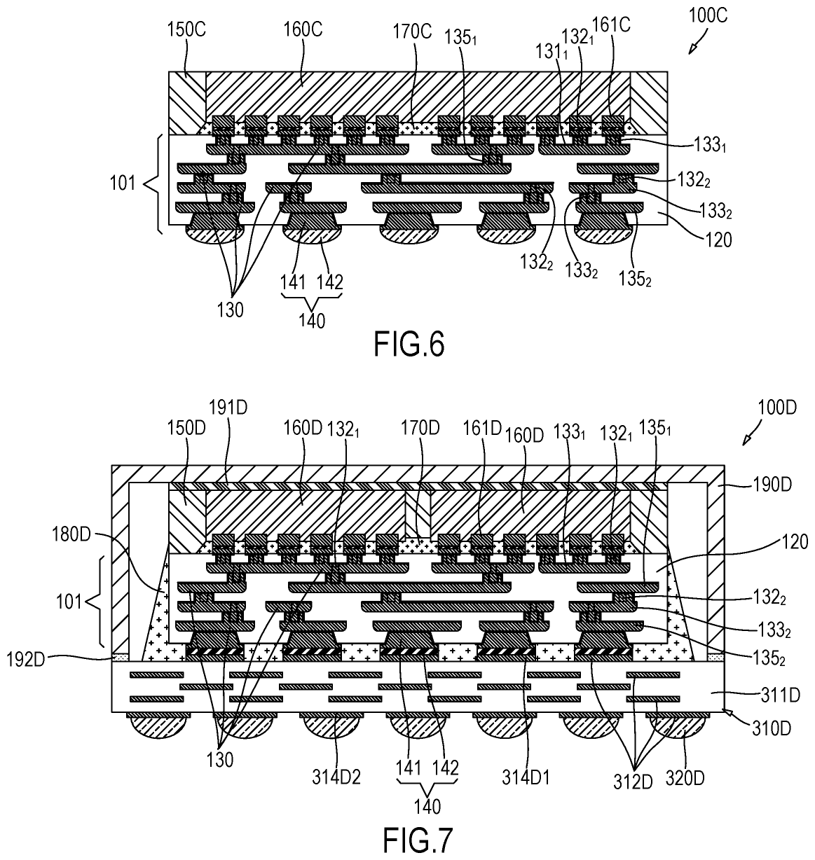

FIG. 6 shows a cross-sectional view of an example electronic device 1000. In the example shown in FIG. 6, electronic device 1000 can comprise electronic component 160C, encapsulant 150C, underfill 170C, and redistribution structure 101. Redistribution structure 101 includes dielectric structure 120 and conductive structure 130, as previously described with reference to FIGS. 2A-2R. In some examples, redistribution structure 101 can further include component interconnects 140. In the example shown in FIG. 6, electronic device 1000 can be formed by providing redistribution structure 101 prior to coupling electronic component 160C to redistribution structure 101.

In accordance with various examples, substrate 110 (FIG. 2R) can be removed from redistribution structure 101 after the process shown in FIG. 2R. In some examples, redistribution structure 101 can be turned over (i.e., rotated 180°) and electronic component 160C can be attached to internal terminals of redistribution structure 101 (e.g., to exposed portions of conductors 132₁ and 133₁, which can also include seed layer 131₁). In some examples, electronic component 160C can comprise or be referred to as a die, chip, package, or passive element. In some examples, the height of electronic component 160C can range from about 20 μm to about 1000 μm.

In accordance with various examples, component interconnects 161C of electronic component 160C can be coupled to the internal terminals of redistribution structure 101. In some examples, component interconnects 161C can comprise or be referred to as bumps, pads, or pillars. In some examples, the height of component interconnects 161C can range from about 1 μm to about 10 μm. In some examples, component interconnects 161C can be coupled to or contact seed layer 131₁. In some examples, component interconnects 161C can be coupled to or contact the bottoms sides of conductors 132₁ and 133₁. In some examples, component interconnects 161C can be coupled to the internal terminals of redistribution structure 101 via solder. In some examples, component interconnects 161C can be coupled to the internal terminals of redistribution structure 101 by a thermocompression bonding process, an ultrasonic bonding process, a laser assisted bonding process, or a hybrid bonding process. In some examples, a conductive structure, such as a UBM or bond pad, can be formed over the internal terminals of redistribution structure 101 after removal of the substrate 110, and component interconnects 161C can be coupled to or contact said conductive structure.

Underfill 170C can be provided between redistribution structure 101 and electronic component 160C. In some examples, underfill 170C can contact redistribution structure 101 (e.g., dielectric structure 120 or conductive structure 130), component interconnects 161C, and/or electronic component 160C. In some examples, underfill 170C can comprise or be referred to as capillary underfill (CUF), non-conductive pasted (NCP), non-conductive film (NCF), or anisotropic conductive film (ACF). In some examples, underfill 170C can be injected into the volume between electronic component 160C and redistribution structure 101 after coupling electronic component 160C to redistribution structure 101. In some examples, underfill 170C can be pre-coated onto redistribution structure 101 prior to coupling electronic component 160C to redistribution structure 101. In some examples, underfill 170C can be pre-coated on electronic component 160C prior to coupling electronic component 160C to redistribution structure 101. In some examples, a curing process (for example, a thermal curing process or a photocuring process) of underfill 170C can be performed.

In some examples, encapsulant 150C can be disposed over redistribution structure 101, electronic component 160C, and underfill 170C. In some examples, encapsulant 150C can cover or contact redistribution structure 101, electronic component 160C, and underfill 170C. In some examples, underfill 170C can be omitted, and encapsulant 150C can be filled between electronic component 160C and redistribution structure 101. In some examples, encapsulant 150C can be located over a top side of electronic component 160C. In some examples, encapsulant 150C can be coplanar with the top side of electronic component 160C.

FIG. 7 shows a cross-sectional view of an example electronic device 100D. In the example shown in FIG. 7, electronic device 100D can comprise one or more electronic component(s) 160D, redistribution structure 101, encapsulant 150D, underfill 170D, base substrate 310D, external interconnects 320D, underfill 180D, lid 190D, and interface materials 191D and 192D. Redistribution structure 101 includes dielectric structure 120, conductive structure 130, and component interconnects 140, as previously described with respect to FIGS. 2A-2R. In the example shown in FIG. 7, electronic device 100D can be formed by providing redistribution structure 101 prior to coupling electronic components 160D to redistribution structure 101.

In accordance with various examples, base substrate 310D can comprise dielectric structure 311D and conductive structure 312D. In some examples, dielectric structure 311D can comprise one or more layers of dielectric materials interleaved with the layers of conductive structure 312D. In some examples, the dielectric materials can comprise PI, BCB, PBO, resin, or ABF. In some examples, conductive structure 312D can comprise one or more conductive layers defining signal distribution elements (e.g., traces, vias, pads, conductive paths, or UBM). Conductive structure 312D can comprise substrate inward terminal 314D1 and substrate outward terminal 314D2. In some examples, substrate inward terminal 314D1 can comprise pads, lands, UBM, or studs. In some examples, substrate outward terminal 314D2 can comprise pads, lands, or UBM. External interconnects 320D can comprise solder balls, bumps, pads, or pillars. External interconnects 320D can be coupled to substrate outward terminal 314D2 of base substrate 310D. In some examples, outward terminal 314D2 can comprise an LGA (land grid array).

In some examples, base substrate 310D can be a pre-formed substrate. Pre-formed substrates can be manufactured prior to attachment to an electronic device and can comprise dielectric layers between respective conductive layers. The conductive layers can comprise copper and can be formed using an electroplating process. The dielectric layers can be relatively thicker non-photo-definable layers, can be attached as a pre-formed film rather than as a liquid, and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or ABF. The pre-formed substrate can include a permanent core structure or carrier such as, for example, a dielectric material comprising BT or FR4, and dielectric and conductive layers can be formed on the permanent core structure. In other examples, the pre-formed substrate can be a coreless substrate omitting the permanent core structure, and the dielectric and conductive layers can be formed on a sacrificial carrier and removed after formation of the dielectric and conductive layers and before attachment to the electronic device. The pre-formed substrate can be referred to as a printed circuit board (PCB) or a laminate substrate. Such pre-formed substrates can be formed through semi-additive or modified-semi-additive processes.

In some examples, base substrate 310D can be an RDL substrate. RDL substrates can comprise one or more conductive layers and one or more dielectric layers and (a) can be formed layer by layer over an electronic device to which the RDL substrate is electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers and define respective conductive patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process and can include a photolithographic mask through which light is exposed to photo-pattern desired features such as vias in the dielectric layers. The dielectric layers can be made from photo-definable organic dielectric materials such as, for example, PI, BCB, or PBO. Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, and could interfere with the light from the photo-patterning process. In some examples, such filler-free characteristics of filler-free dielectric materials can permit a reduction in the vertical thickness or height of the resulting dielectric layer. Although the photo-definable dielectric materials described above can be organic materials, in some examples the dielectric materials of the RDL substrates can comprise one or more inorganic dielectric layers. Some examples of inorganic dielectric layer(s) can comprise silicon nitride (Si3N4), silicon oxide (SiO2), or silicon oxynitride (SiON). The inorganic dielectric layer(s) can be formed by growing the inorganic dielectric layers using an oxidation or nitridization process instead using photo-defined organic dielectric materials. Such inorganic dielectric layers can be filler-free, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as coreless substrates.

Component interconnects 140 of redistribution structure 101 can be coupled to substrate inward terminals 314D1 of base substrate 310D. In some examples, component interconnects 140 can be coupled to inward terminal 314D1 by thermal compression bonding, ultrasonic bonding, or laser assisted bonding. In some examples, solder can be interposed between component interconnects 140 and inward terminals 314D1. In some examples, underfill 180D can be interposed between redistribution structure 101 and base substrate 310D. In some examples, underfill 180D can be located over or can cover the lateral sides of the redistribution structure 101.

In some examples, lid 190D can be coupled to electronic components 160D via interface material 191D. Lid 190D can be coupled to base substrate 310D via interface material 192D. In some examples, lid 190D can comprise a heat spreader and be coupled (e.g., thermally and/or mechanically) to electronic component 160D via a thermal adhesive interface material 191D. For example, interface material 191D can comprise a thermal interface material (TIM). In some examples, interface material 191D can also be interposed between encapsulant 150D and lid 190D. Lid 190D can comprise or be referred to as a cover, case, or housing. In some examples, lid 190D can provide electromagnetic interference (EMI) shielding. The height of lid 190D can range from about 100 μm to about 1000 μm. Interface material 192D can coupled lid 190D to the upper side of base substrate 310D. Interface material 192D can comprise, for example, an adhesive. In some examples, interface material 192D can be electrically insulating. In some examples, interface material 192D can be electrically conductive and can couple lid 190D to conductive structure 312D of base substrate 310D. Lid 190D can dissipate heat from electronic components 160D and/or can protect redistribution structure 101 and electronic components 160D from the external environment.

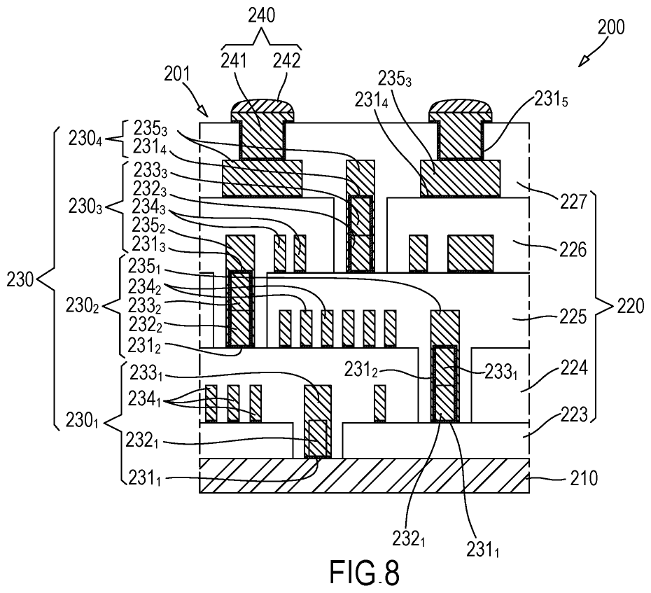

FIG. 8 shows a cross-sectional view of an example electronic component 200. In the example shown in FIG. 8, electronic component 200 can comprise substrate 210 and redistribution structure 201. Redistribution structure 201 can comprise dielectric structure 220 and conductive structure 230. In some examples, redistribution structure 201 can further comprise component interconnects 240. Electronic component 200 can be similar to electronic component 100 shown in FIG. 1, but with conductive structure 230 of electronic component 200 comprising a pad-less small vias.

Conductive structure 230 can include one or more conductive patterns, such as conductive pattern 230₁, conductive pattern 230₂, conductive pattern 230₃, and conductive pattern 230₄, interleaved with one or more dielectric layers, such as dielectric layer 223, 224, 225, 226, and 227, of dielectric structure 120. Conductive pattern 230₁ can comprise seed layer 231₁, conductors 232₁, conductors 233₁, and traces 234₁. Conductive pattern 230₂ can comprise seed layer 231₂, traces 234₂, conductors 235₁, conductors 232₂, and conductors 233₂. Conductive pattern 230₃ can comprise seed layer 231₃, conductors 235₂, conductors 232₃, conductors 233₃, and traces 234₃. Conductive pattern 130₄ can comprise seed layer 231₄ and conductors 135₂. Component interconnects 240 can each comprise contact pad 241 and terminal tip 242. In some examples, conductive structure 230 can electrically couple component interconnects 240 to substrate 210. In some examples, redistribution structure 201 can provide electrical coupling between external electrical components and substrate 110.

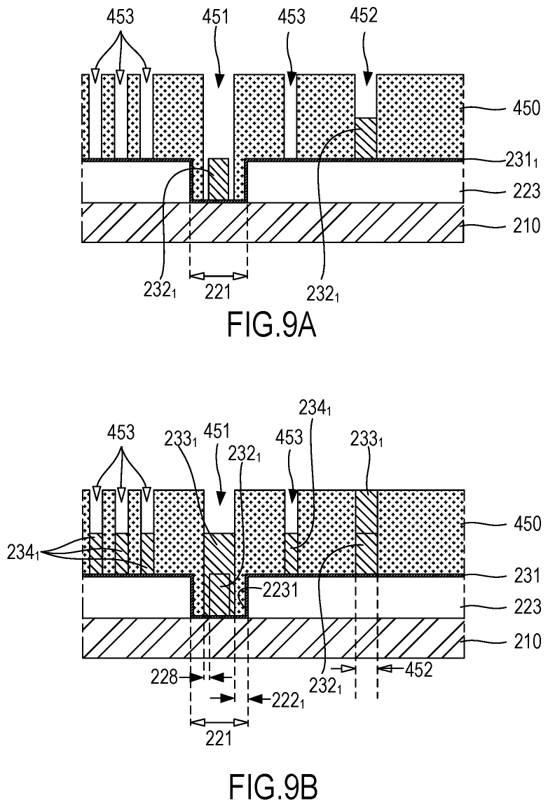

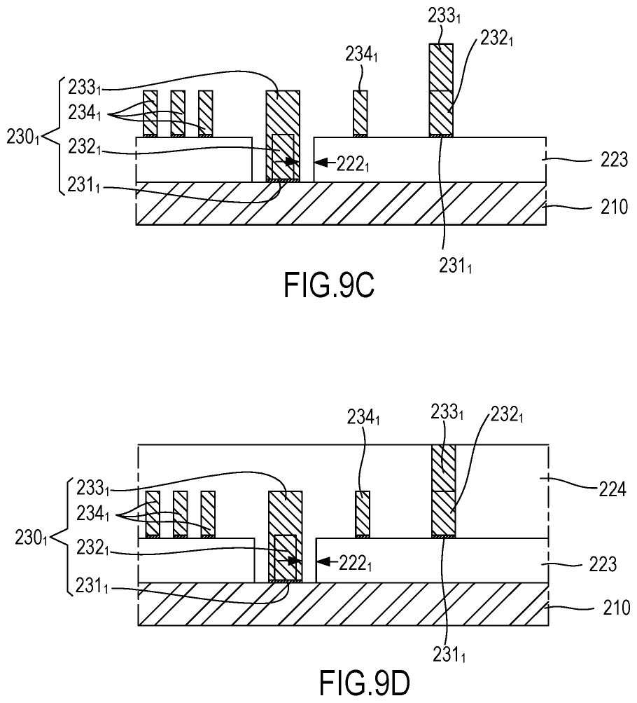

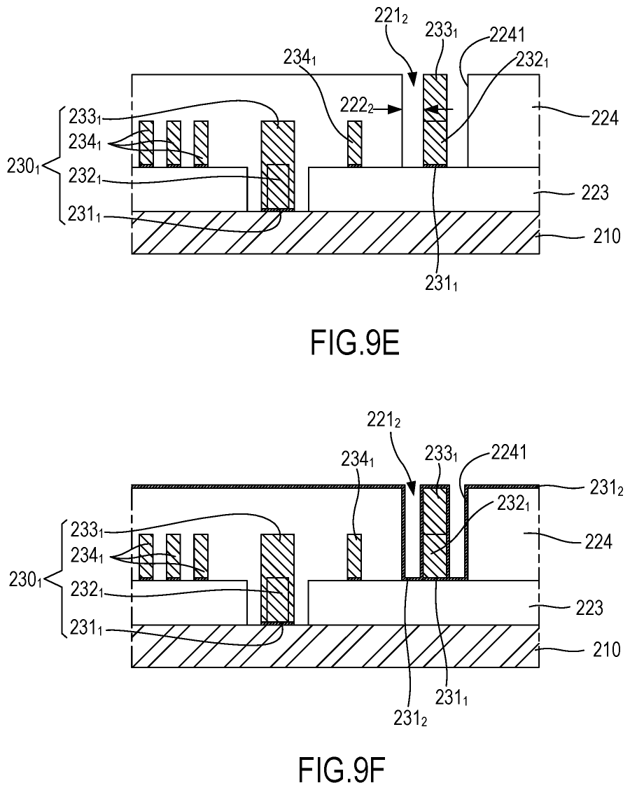

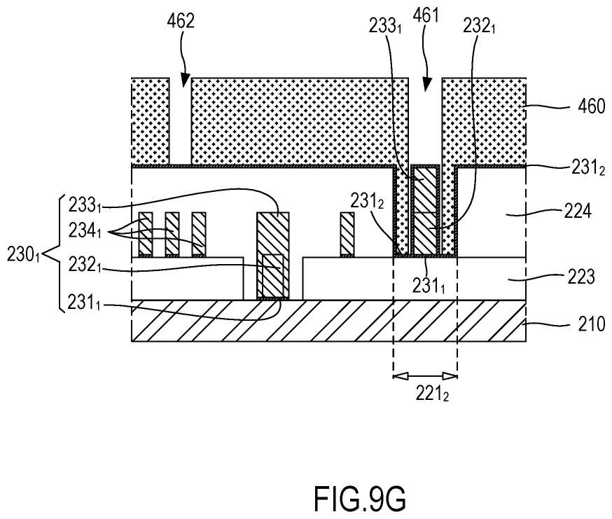

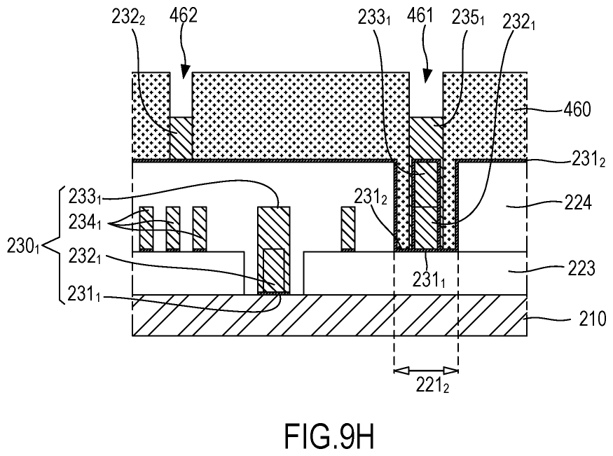

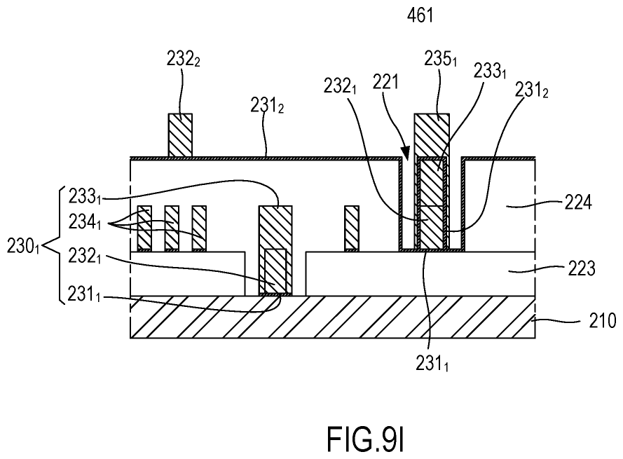

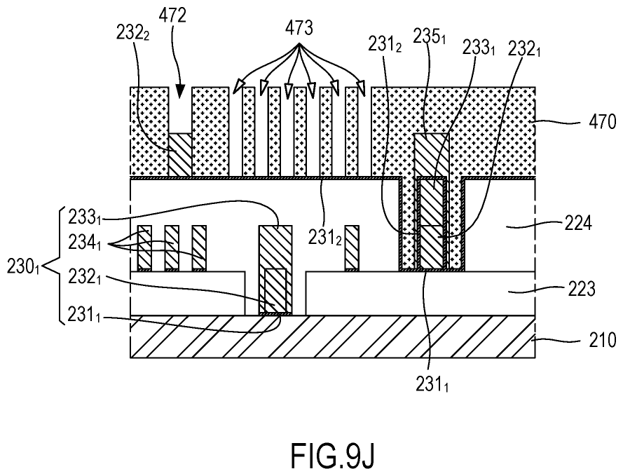

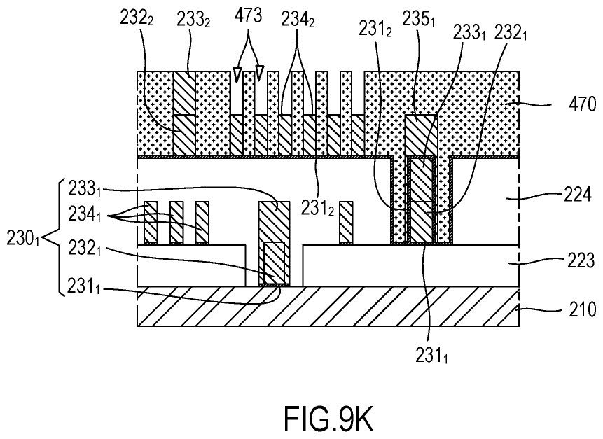

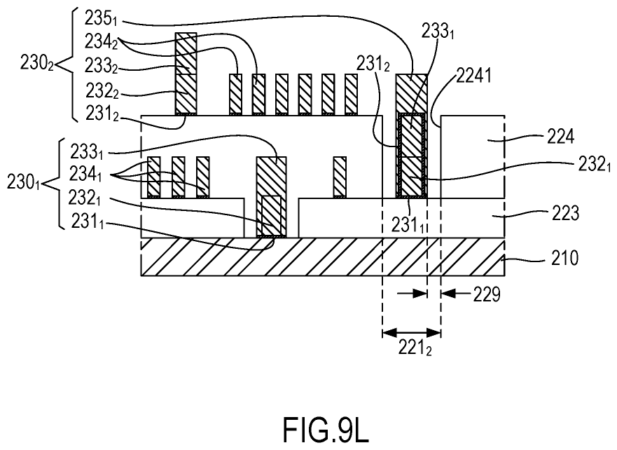

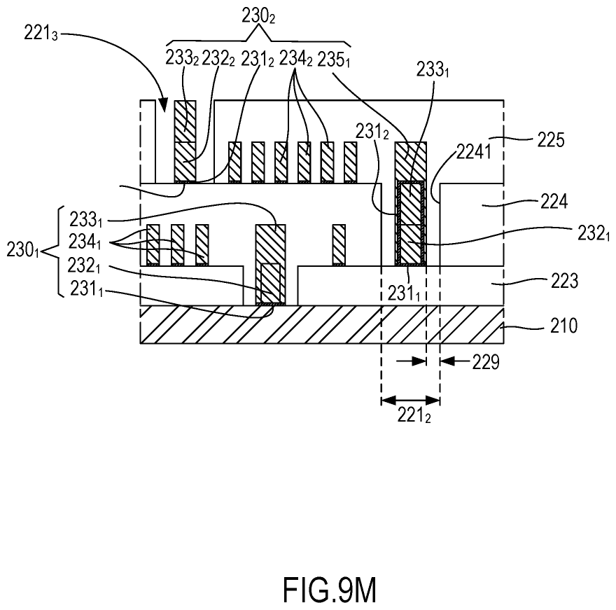

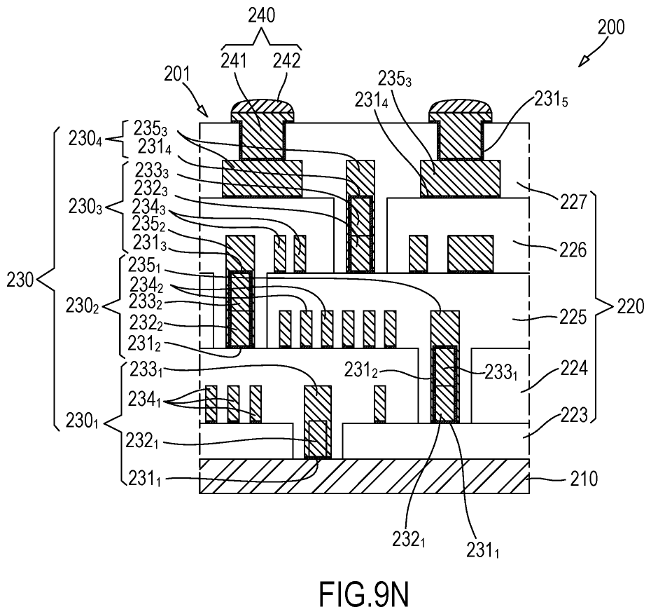

FIGS. 9A to 9N show cross-sectional views of an example method for manufacturing electronic component 200. FIG. 9A shows a cross-sectional view of electronic component 200 at an early stage of manufacture. The processes for forming electronic component 200 to the stage shown in FIG. 9A can be similar to or the same as the processes for forming electronic component 100, as described above with reference to FIGS. 2A-2G. In accordance with various embodiments, the diameter or width of via 451 in photoresist 450 is less than the diameter or width of via 221 in dielectric layer 223. The diameter or width of via 452 in photoresist 450 can be similar or equal to the diameter or width of the conductor 232₁ located on dielectric layer 223. In some examples, photoresist 450 can be provided on seed layer 231₁ and then via 451, via 452, and RDL vias 453 can be provided by patterning photoresist 450. The process for patterning photoresist 450 can be similar to or the same as the process for patterning photoresists 410 and 420, as described above with reference to FIGS. 2D and 2G. In some examples, vias 451 and 452 can be substantially circular when viewed from the top (e.g., vias 451 and 452 can have a circular cross-section in a horizontal plane). In some examples, RDL vias 453 can be substantially linear when viewed from the top (e.g., RDL vias 453 can have a rectangular cross-section in a horizontal plane).

In some examples, via 451 can be patterned to have a diameter that is less than the diameter of via 221 greater than the diameter of conductor 232₁. In some examples, conductor 232₁ and a portion of seed layer 231₁ can be exposed through via pattern 451. The diameter or width of via 451 can range from about 1 μm to about 100 μm. In some examples, the diameter or width of via 452 can range from about 0.5 μm to about 100 μm. In some examples, RDL vias 453 can be provided on dielectric layer 223. The width of RDL vias 453 can be less than or equal to the widths of vias 451 and 452. The width of each RDL via 453 can range from about 0.1 μm to about 100 μm.

FIG. 9B shows a cross-sectional view of electronic component 200 at a later stage of manufacture. In the example shown in FIG. 9B, conductors 233₁ and traces 234₁ can be provided on seed layer 231₁. In some examples, a conductor 233₁ can be provided on seed layer 231₁ and conductor 232₁ by forming the conductor 233₁ in via 451. Via 451 can allow the conductor 233₁ to surround, cover, or contact the conductor 232₁ within via 451. The conductor 233₁ can extend into via 221 and into the gap 228 between conductor 232₁ and photoresist 450.

Conductor 233₁ can cover conductor 232₁ and a portion of seed layer 231₁ exposed along a bottom (or floor) of via 451. In some examples, conductor 233₁ can cover the top side and the lateral side of the conductor 232₁ in via 451. The diameter or width of conductor 233₁ in via 451 can be greater than the diameter or width of the conductor 232₁ in via 451. The inner wall 2231 of dielectric layer 223 defines via 221. Inner wall 2231 can be spaced from a lateral side of conductor 233₁ by a gap 222₁ that is less than the via filling limit. In some examples, a portion of conductor 233₁ on the top side of conductor 232₁ can protrude upward and can be coplanar with the top side of traces 234₁. In some examples, the conductor 232₁ and conductor 233₁ in via 451 can be coupled to an input/output terminal of substrate 210.

In some examples, a conductor 233₁ can also be provided on the conductor 232₁ in via 452 of photoresist 420. Via 452 can allow the conductor 233₁ to contact the top side of the conductor 232₁ located on dielectric layer 223. In some examples, traces 234₁ can be provided on seed layer 231₁ by providing conductive material (e.g., Cu, Ni, Au, Ag, Al, Ti, TiW, or other suitable electrically conductive material) in RDL vias 453. RDL vias 453 can allow trace 234 to be provided on dielectric layer 223. The materials and manufacturing process of conductors 233₁ and traces 234₁ can be similar to or the same as the materials and the manufacturing process, respectively, of conductors 133₁ and traces 134₁, as discussed above with respect to FIG. 2H.

The conductor 233₁ over dielectric layer 223 can contact a top side of the conductor 232₁ and in via 452. The diameter or width of conductor 233₁ can be similar or equal to the diameter or width of the conductor 232₁ in via 452. In some examples, a portion of the conductor 233₁ on the top side of conductor 232₁ can protrude upward and can be above a top side of traces 234₁. In some examples, conductors 232₁ and 233₁ in via 451 or via 452 can be coupled to a trace 234 on the same layer (e.g., trace 234₁), to a conductor on another layer (e.g., conductor 235₁ of conductor 232₂, with momentary reference to FIG. 8), or to a trace 234 on another layer (e.g., trace 234₂, with momentary reference to FIG. 8). In some examples, the combined height of the conductor 232₁ and conductor 233₁ in via 451 can be similar or the same as the combined height of the conductor 232₁ and conductor 233₁ in via 452. In some examples, the height of a top side of the conductor 233₁ in via 451, relative to substrate 210 or dielectric layer 223, can be different from the height of a top side of the conductor 233₁ in via 452.

In some examples, conductors 233₁ can be pad-less or have a generally uniform diameter. For example, conductors 233₁ that include pads can have a pad portion with a first diameter and a non-pad portion, which may extend vertically from the pad portion and has a second diameter that is less than the first diameter. In some examples, the diameter or width of conductor 233₁ and the width of a trace 234₁ connected or contacting conductor 233₁ can be similar. For example, the width of trace 234₁ can be at least 90% of the width of 233₁. Thus, the width of the conductive via (e.g., vertical portion of conductor 233₁) can be similar to or the same as the width of the trace 234₁ connected to the via. The width of the via being similar or equal to the width of the trace tends to reduce or suppress electrical signal loss through the via.

FIG. 9C shows a cross-sectional view of electronic component 200 at a later stage of manufacture. In the example shown in FIG. 9C, photoresist 450 can be removed and portions of seed layer 231₁ not covered by conductors 232₁, conductors 233₁, or traces 234₁ can be removed. The process of removing photoresist 450 can be similar to or the same as the process of removing photoresist 410 or 420, as described above. In some examples, conductors 232₁, conductors 233₁, and traces 234₁ can be used as a mask, and the portion of seed layer 231₁ outside the footprints of conductors 232₁, conductors 233₁, and traces 234₁ can be removed. The process of removing seed layer 231₁ can be similar to or the same as the process of removing seed layer 131₁, as described above with reference to FIG. 2J.

In some examples, seed layer 231₁, conductors 232₁, conductors 233₁, and traces 234₁ located on substrate 210 and dielectric layer 223 can be referred to as conductive pattern 230₁. Conductive pattern 230₁ can comprise one or more conductive components defining signal distribution elements such as traces, vias, conductive paths, or UBM. In some examples, conductors 232₁ and conductors 233₁ can be referred to as a conductive via. In some examples, traces 234₁ can comprise or be referred to as a RDL or RDL pattern. In some examples, the width of each of conductors 232₁ and conductors 233₁ is similar or equal to the width of traces 234.

FIG. 9D shows a cross-sectional view of electronic component 200 at a later stage of manufacture. In the example shown in FIG. 9D, dielectric layer 224 of dielectric structure 220 can be provided on dielectric layer 223 of dielectric structure 220 and on conductive pattern 230₁. The elements, features, materials, and formation processes of dielectric layer 224 can be similar to or the same as the elements, features, materials, and formation processes described above for dielectric layer 123. In some examples, the top side of conductor 233₁ can be exposed at the top side of dielectric layer 224. In some examples, the top side of conductor 233₁ can be coplanar with the top side of dielectric layer 224.

FIG. 9E shows a cross-sectional view of electronic component 200 at a later stage of manufacture. In the example shown in FIG. 9E, dielectric layer 224 can be patterned to provide via 221₂ in dielectric layer 224. The elements, features, materials, and patterning process of dielectric layer 224 can be similar to or the same as those described above with respect to dielectric layers 123 and 124. Via 221₂ can be defined by inner wall 224₁ of dielectric layer 224. The diameter or width of via 221₂ is greater than the diameter or width, respectively, of the conductors 232₁ and 233₁ located in an exposed by via 221₂. The diameter or width of via 221₂ can range from about 1 μm to about 100 μm.

In accordance with various examples, via 221₂ can expose the lateral sides of seed layer 231₁ and conductor 232₁, and a top side and lateral sides of conductor 233₁. In accordance with various examples, a gap 222₂ can be defined between the lateral sides of conductors 232₁, 233₁ and inner wall 224₁ of dielectric layer 224. In some examples, gap 222₂ can range from about 5 μm to about 20 μm.

FIG. 9F shows a cross-sectional view of electronic component 200 at a later stage of manufacture. In the example shown in FIG. 9F, seed layer 231₂ can be provided on dielectric layer 224 and in via 221. In some examples, seed layer 231₂ can be provided on conductors 232₁, 233₁ and seed layer 231₁ in via 221₂. In some examples, seed layer 231₂ can be provided on the lateral sides of conductor 232₁, conductor 233₁, and seed layer 231₁, and the top side of conductor 233₁. Seed layer 231₂ can also be provided on the top side and inner wall 224₁ of dielectric layer 224. The elements, features, materials, and manufacturing processes of seed layer 231₂ can be similar to or the same as those of seed layers 131₁ and 131₂, as described above with reference to FIGS. 2C and 2M.

FIG. 9G shows a cross-sectional view of electronic component 200 at a later stage of manufacture. In the example shown in FIG. 9G, photoresist 460 can be provided on seed layer 231₂. Photoresist 460 can be patterned to provide vias 461 and 462 in photoresist 460. The elements, features, materials, and patterning process of photoresist 460 can be similar to or the same as those described above with respect to photoresists 410, 420, and 430. The diameter or width of via 461 can be less than the diameter or width of via 221₂ in dielectric layer 224. The diameter or width of via 461 can be greater than the diameter or width of conductors 232₁ and 233₁ such that a gap or space is provided between conductors 232₁, 233₁ and photoresist 460. The diameter or width of via 462 can be similar or equal to the diameter or width of conductors 232₁.

FIG. 9H shows a cross-sectional view of electronic component 200 at a later stage of manufacture. In the example shown in FIG. 9H, conductor 235₁ and conductor 232₂ can be provided on seed layer 231₂. Conductor 235₁ can be provided in via 461 and can cover conductors 232₁ and 233₁ in via 221₂. Conductor 235₁ can extend into the gap between conductors 232₁, 233₁ and photoresist 460. Conductor 235₁ can extend into via 221 and around lateral sides of conductor 232₁ and conductor 233₁. Seed layer 231₂ can be interposed between conductor 235₁ and conductors 232₁, 233₁ in via 221₂.

Conductor 232₂ can be provided in via pattern 462 and can contact seed layer 231₂. The height of conductor 232₂, as measured from the top of dielectric layer 224, can be similar or equal to the height of conductor 235₁, as measured from the top of dielectric layer 224. In some examples, the top side of conductor 232₂ can be coplanar with the top side of conductor 235₁. Conductor 235₁ can be coupled to conductors 232₁ and 233₁, one or more trace(s) 234₁, and/or one or more trace(s) 234₂, with momentary reference to FIG. 9K. The elements, features, materials, and manufacturing processes of conductors 232₂ and 235₁ can be similar to or the same as those of conductors 132₂ and 135₁, as previously described with referent to FIGS. 2N and 2O.

In accordance with various examples, conductor 235₁ can be pad-free. For example, conductor 235₁ can have a uniform, or substantially, uniform diameter between the top side and bottom side of conductor 235₁. Stated differently, a diameter the annular, or ring-shaped, portion of conductor 235₁ that is located around conductors 232₁ and 233₁ can be equal to the diameter of the upper portion of conductor 235₁ that is located over the top side of conductor 233₁.

FIG. 9I shows a cross-sectional view of electronic component 200 at a later stage of manufacture. In the example shown in FIG. 9I, photoresist 460 can be removed. The process of removing photoresist 460 can be similar to or the same as the process of removing photoresist 410, 420, or 430, as described above with reference to FIGS. 2F, 2I, and 2O. Removal of photoresist 460 can expose seed layer 231₂ and the laterals sides of conductor 232₂ and conductor 235₁.

FIG. 9J shows a cross-sectional view of electronic component 200 at a later stage of manufacture. In the example shown in FIG. 9J, photoresist 470 can be provided on seed layer 231 and over conductor 232₂ and conductor 235₁. In accordance with various examples, photoresist 470 can be patterned to provide via 472 and RDL vias 473. Via 472 can be located over and can expose conductor 232₂. RDL vias 473 can expose seed layer 231₂. The diameter or width of via 472 similar or equal to the diameter or width of conductors 232₂. The diameter or width of RDL vias 473 can be similar or equal to the diameter or width of conductors 232₁, 232₂, 233₁, 233₁, or 235₁. The elements, features, materials, and patterning process of photoresist 470 can be similar to or the same as those described above with respect to photoresists 410, 420, and 430.

FIG. 9K shows a cross-sectional view of electronic component 200 at a later stage of manufacture. In the example shown in FIG. 9K, conductor 233₂ and traces 234₂ can be provided on conductor 232₂ and seed layer 231₂, respectively. Conductor 233₂ can be provided in via 472 and can on or contacting conductor 232₂. Traces 234₂ can be provided on seed layer 231₂ by providing conductive material (e.g., Cu, Ni, Au, Ag, Al, Ti, TiW, or other suitable electrically conductive material) in RDL vias 473. The elements, features, materials, and manufacturing process of conductor 233₂ can be similar to or the same as those described above with respect to conductors 133₁ and 233₁. The elements, features, materials, and manufacturing process of traces 234₂ can be similar to or the same as those described above with respect to traces 134₁, 134₂, and 234₁.

FIG. 9L shows a cross-sectional view of electronic component 200 at a later stage of manufacture. In the example shown in FIG. 9L, photoresist 470 and exposed portions of seed layer 231₂ are removed. Removal of photoresist 470 can expose conductors 232₂, 233₂, 235₁, traces 234₂, and seed layer 231₂. The process of removing photoresist 470 can be similar to or the same as the process of removing photoresist 410, 420, or 430, as described above with reference to FIGS. 2F, 2I, and 2O.

In accordance with various examples, removal of exposed portions of seed layer 231₂ can expose the top side and inner walls 224₁ of dielectric layer 224 and a portion of the top side of dielectric layer 223 (e.g., the portion of dielectric layer 223 that forms the floor of via 221₂). In some examples, conductor 232₂, conductor 233₂, conductor 235₁, and traces 234₂ can be used as a mask, and the portion of seed layer 231₂ outside the footprints of conductor 232₂, conductor 233₂, conductor 235₁, and traces 234₂ is removed. The process of removing seed layer 231₂ can be similar to or the same as the process of removing seed layer 131₁, as described above with reference to FIG. 2J. In some examples, seed layer 231₂, conductor 235₁, traces 234₂, conductor 232₂, and conductor 233₂ can be referred to as conductive pattern 230₂. In response to removal of photoresist 470 and seed layer 231₂, the gap 229 defined by conductor 235₁ and inner wall 224₁ of dielectric layer 224 may be devoid of material.

FIG. 9M shows a cross-sectional view of electronic component 200 at a later stage of manufacture. In the example shown in FIG. 9M, dielectric layer 225 can be provided over conductive pattern 230₂ (e.g., conductor 232₂, conductor 233₂, traces 234₂, and conductor 235₁) and dielectric layer 224. Via 221₃ can be provided in dielectric layer 225. Conductors 232₂ and 233₂ can be exposed in via 221₃. Via 221₃ can also expose a lateral side (or terminal end) of seed layer 231₂ and a portion of the upper side of dielectric layer 224. This process can be similar to or the same as the process shown in FIG. 9F.

In accordance with various examples, dielectric layer 225 can extend into via 221₂ such that dielectric layer 225 is located in the gap 229 between conductor 235₁ and inner wall 224₁ of dielectric layer 224. The portion of dielectric layer 225 in via 221₂ can also contact an upper side of dielectric layer 223. In some examples, an upper side of dielectric layer 225 can be coplanar with the upper side of conductor 233₂.

FIG. 9N shows a cross-sectional view of electronic component 200 at a later stage of manufacture. In the example shown in FIG. 9N, the steps illustrated in FIGS. 9F to 9M and FIGS. 2P to 2R can be performed to provide conductive patterns 230₃ and 230₄, dielectric layers 226 and 227, and interconnect structures 240. Conductive pattern 230₃ can comprise seed layer 231₃, conductor 235₂, conductors 232₃, conductors 233₃, and traces 234₃. Conductive pattern 130₄ can comprise seed layer 231₄ and conductors 135₂. Conductive pattern 130₄ can also comprise traces, similar to traces 234₃, located over dielectric layer 226. Component interconnects 240 can each comprise contact pad 241 and terminal tip 242.

In accordance with various examples, individual electronic components 200 can be provided by a singulation process. In some examples, the singulation process can include sawing or cutting through substrate 210 and dielectric structure 220. In some examples, the singulation process can also cut through conductive structure 230. In some examples, in response to singulation, lateral sides of substrate 210, dielectric structure 120, or conductive structure 230 can be coplanar.

In accordance with various examples, redistribution structure 201 can be provided having a pad-less, small-diameter conductive vias, such as the conductive via formed by conductor 232₁ and conductor 233₁, the conductive via formed by conductor 232₁, conductor 233₁, and conductor 235₁, the conductive via formed by conductor 232₂, conductor 233₂, and conductor 235₂, or the conductive via formed by conductor 232₃, conductor 233₃, and conductor 2353. In this way, even if the resolution of the dielectric material of dielectric structure is low (e.g., if dielectric layer 223, 224, 225, 226, or 227, comprises a low-resolution PI that does not support 10 μm diameter patterns) a pad-less, small-diameter conductive via can be implemented. Electrical loss can be reduced by the pad-less, small-diameter conductive via structure, as a width of the RDL patterns and a width of the conductive vias can be similar or the same. Since the diameter or width of the conductive vias is relatively small due to the pad-less conductive via structure, a greater density and/or smaller-pitch RDL pattern can be provided between the conductive vias.

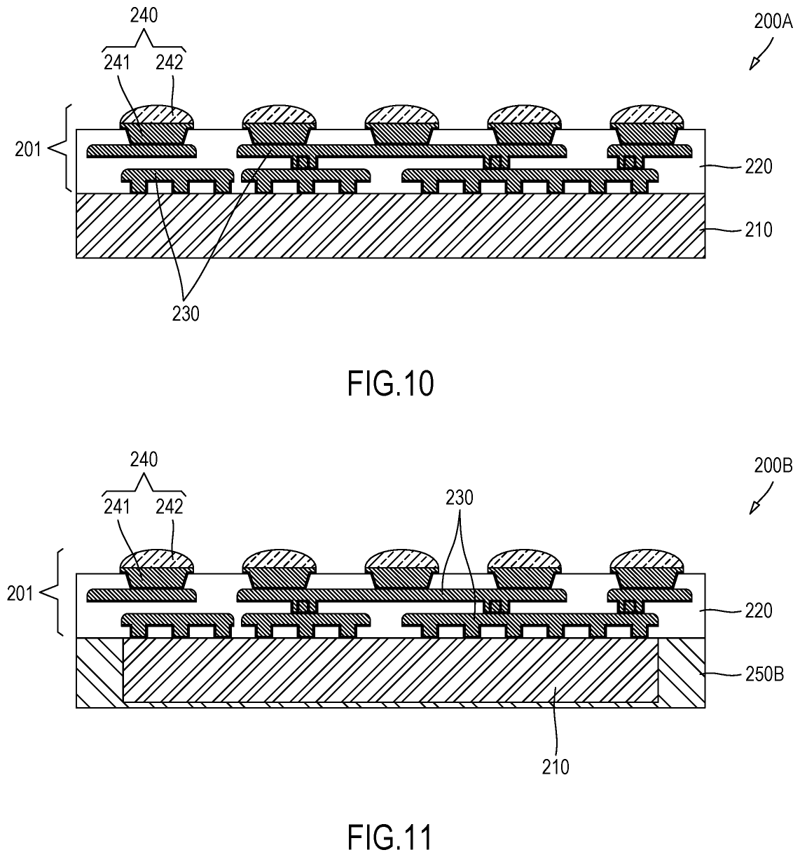

FIG. 10 shows a cross-sectional view of an example electronic device 200A. In the example shown in FIG. 10, electronic device 200A can comprise substrate 210 and redistribution structure 201. Redistribution structure 201 includes dielectric structure 220 and conductive structure 230, as previously described with reference to FIGS. 9A-9N. In some examples, redistribution structure 201 can further include component interconnects 240. In accordance with various examples, electronic device 200A can be manufactured using a process similar to the processes shown in FIGS. 9A-9N. In some examples, electronic device 200A can comprise or be referred to as WLP or WLCSP. Electronic device 200A can be similar to electronic device 100A shown in FIG. 4, but redistribution structure with 201 provided in place of redistribution structure 101. In some examples, redistribution structure 201 of electronic device 200A can comprise pad-less conductive vias.

FIG. 11 shows a cross-sectional view of an example electronic device 200B. In the example shown in FIG. 11, electronic device 200B can comprise substrate 210, redistribution structure 201, and encapsulant 250B. Redistribution structure 201 includes dielectric structure 220 and conductive structure 230, as previously described with reference to FIGS. 9A-9N. In some examples, redistribution structure 101 can further include component interconnects 240. Encapsulant 250B can be similar to encapsulant 150B, as previously described with reference to FIG. 5. Electronic device 200B can be similar to electronic device 100B shown in FIG. 5, but redistribution structure with 201 provided in place of redistribution structure 101. In some examples, redistribution structure 201 of electronic device 200B can comprise pad-less conductive vias.

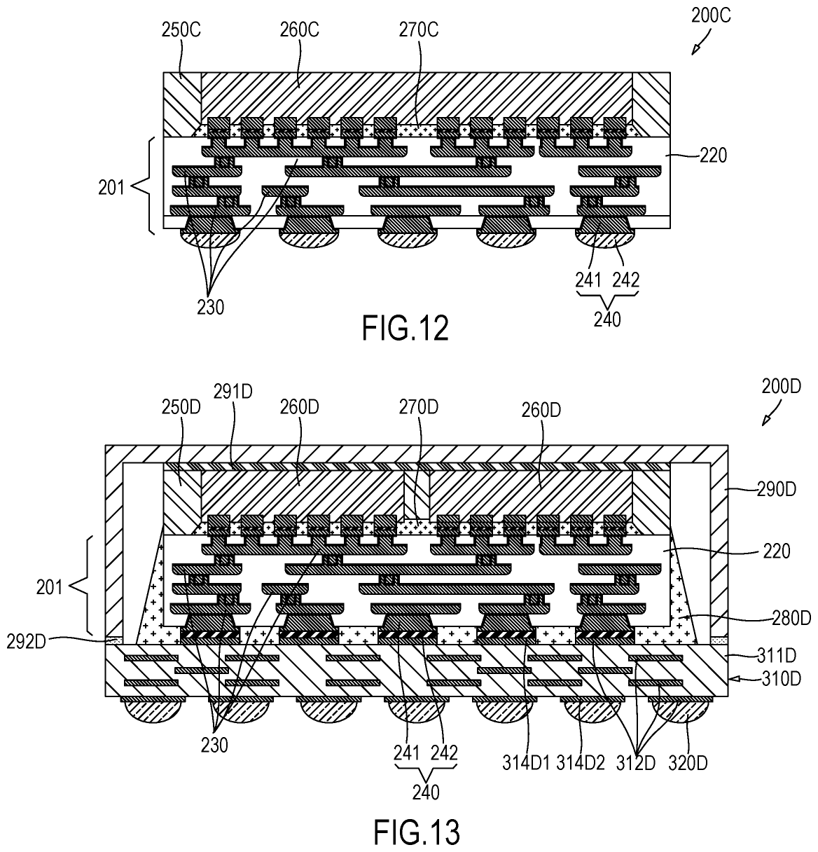

FIG. 12 shows a cross-sectional view of an example electronic device 2000. In the example shown in FIG. 12, electronic device 2000 can comprise electronic component 260C, encapsulant 250C, underfill 270C, and redistribution structure 201. Redistribution structure 201 includes dielectric structure 220 and conductive structure 230, as previously described with reference to FIGS. 9A-9N. In some examples, redistribution structure 901 can further include component interconnects 240. In the example shown in FIG. 12, electronic device 2000 can be formed by providing redistribution structure 201 prior to coupling electronic component 260C to redistribution structure 201. Electronic device 2000 can be similar to electronic device 100C shown in FIG. 6, but redistribution structure with 201 provided in place of redistribution structure 101. In some examples, redistribution structure 201 of electronic device 2000 can comprise pad-less conductive vias.

FIG. 13 shows a cross-sectional view of an example electronic device 200D. In the example shown in FIG. 13, electronic device 200D can comprise electronic component 260D, one or more electronic component(s) 260D, redistribution structure 201, encapsulant 250D, underfill 270D, base substrate 310D, external interconnects 320D, underfill 280D, lid 290D, and interface materials 291D and 292D. Redistribution structure 201 includes dielectric structure 220, conductive structure 230, and component interconnects 240, as previously described with respect to FIGS. 9A-9N. In the example shown in FIG. 13, electronic device 200D can be formed by providing redistribution structure 201 prior to coupling electronic components 260D to redistribution structure 101. Electronic device 200D can be similar to electronic device 100D shown in FIG. 7, but redistribution structure with 201 provided in place of redistribution structure 101. In some examples, redistribution structure 201 of electronic device 2000 can comprise pad-less conductive vias.

Some devices and processes described above can comprise dimple-free conductive vias. The pre-via preparation can leave a small gap (e.g., less than the via filling limit) between a conductor and the wall of the via. Another conductor fills the gap and covers the first conductor to leave a substantially flat top side of the second conductor. The substantially flat top side of the conductor tends to prevent trace patterns above the top side of the conductor from collapsing.

Some examples can comprise pad-less, small-diameter conductive vias formed using pre-via structures. Pad-less, small-diameter conductive vias described herein can also have resolution finer than the resolution of the dielectric layers defining the vias. The pad-less, small-diameter conductive vias tend to enable fine pitch RDLs with improved signal integrity.

The present disclosure includes reference to certain examples; however, it will be understood by those skilled in the art that various changes may be made, and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. A method of making a semiconductor device, comprising:
providing a first dielectric layer, wherein an inner wall of the first dielectric layer defines a first via;
providing a first photoresist over the first dielectric layer and in the first via, wherein an inner wall of the first photoresist defines a second via extending into the first via;
providing a first conductor in the second via, wherein a first gap is defined between a lateral side of the first conductor and the inner wall of the first dielectric layer;
removing the first photoresist from the first gap defined between the lateral side of the first conductor and the inner wall of the first dielectric layer;
providing a second photoresist over the first dielectric layer, wherein the second photoresist defines a third via over the first conductor; and
providing a second conductor in the third via, wherein the second conductor extends into the first gap defined between the lateral side of the first conductor and the inner wall of the first dielectric layer.

2. The method of claim 1, further comprising:
providing a second dielectric layer over a top side of the second conductor; and
providing traces over the second dielectric layer above the second conductor, wherein the traces above the second conductor comprise vertical sidewalls that are substantially parallel.

3. The method of claim 1, further comprising providing a seed layer over the first dielectric layer and in the first via, wherein the first conductor and the second conductor are provided over the seed layer.

4. The method of claim 1, wherein a portion of the second conductor that extends into the first gap comprises an annular geometry.

5. The method of claim 1, wherein a first side of the first conductor is coplanar with a first side of the second conductor.

6. The method of claim 1, further comprising:
providing a third conductor;
providing a fourth conductor protruding above the third conductor;
providing a second dielectric layer over the third conductor and the fourth conductor, wherein a second gap is defined between an inner wall of the second dielectric layer and a lateral side of the fourth conductor; and
providing a fifth conductor over the fourth conductor and the second dielectric layer, wherein the fifth conductor extends into the second gap defined between the lateral side of the fourth conductor and the inner wall of the second dielectric layer,
wherein the first dielectric layer is provided over a top side of the fifth conductor.

7. The method of claim 1, further comprising:
removing the second photoresist to define a second gap between a lateral side of the second conductor and the inner wall of the first dielectric layer; and
providing a second dielectric layer over the second conductor, wherein the second dielectric layer fills the second gap.

8. The method of claim 1, wherein the lateral side of the first conductor is separated from the inner wall of the first dielectric layer by a width less than about 10 micrometers.

9. The method of claim 8, wherein providing the second conductor in the third via further comprises:
providing a plating accelerant in the first gap defined between the lateral side of the first conductor and the inner wall of the first dielectric layer; and
plating the second conductor in the third via using the plating accelerant to increase a plating rate.

10. A method of making a semiconductor device, comprising:
providing a first conductor;
providing a second conductor protruding above the first conductor;
providing a first dielectric layer, wherein a first gap is defined between an inner wall of the first dielectric layer and a lateral side of the second conductor;
providing a first seed layer over the second conductor, over the first dielectric layer, and in the first gap; and
providing a third conductor over the first seed layer, wherein third conductor extends into the first gap defined between the lateral side of the second conductor and the inner wall of the first dielectric layer.

11. The method of claim 10, wherein third conductor extends through the first gap and into a second gap defined between a lateral side of the first conductor and the inner wall of the first dielectric layer.

12. The method of claim 10, wherein providing the third conductor over the first seed layer further comprises:
providing a plating accelerant in the first gap defined between the lateral side of the second conductor and the inner wall of the first dielectric layer; and
plating the second conductor using the plating accelerant to increase a plating rate.

13. The method of claim 10, further comprising:
providing a second dielectric layer over the first dielectric layer and the third conductor, wherein an inner wall of the second dielectric layer defines a first via over the third conductor;
providing a second seed layer over the third conductor and the second dielectric layer;
providing a photoresist in the first via, wherein the photoresist defines a second via extending into the first via; and
providing a fourth conductor in the second via, wherein a second gap is defined between a lateral side of the fourth conductor and the inner wall of the second dielectric layer.

14. The method of claim 10, wherein the lateral side of the second conductor is separated from the inner wall of the first dielectric layer by less than about 10 micrometers.

15. The method of claim 10, further comprising:
providing a second dielectric layer over the first dielectric layer and a top side of the third conductor; and
providing traces over the second dielectric layer and above the third conductor, wherein the traces above the third conductor comprise vertical sidewalls that are substantially parallel.

16. The method of claim 10, further wherein a portion of the third conductor between the inner wall of the first dielectric layer and the lateral side of the second conductor comprises an annular geometry.

17. A semiconductor device, comprising:
a first dielectric layer comprising an inner wall that defines a via;
a seed layer disposed over the first dielectric layer and in the via;
a first conductor disposed over the seed layer and in the via, wherein the first conductor comprises a cylindrical geometry;
and
a second conductor disposed over the first conductor and the first dielectric layer, wherein the second conductor extends into a gap defined between the inner wall of the first dielectric layer and a lateral side of the first conductor.

18. The semiconductor device of claim 17, wherein a portion of the second conductor extending into the gap comprises an annular geometry.

19. The semiconductor device of claim 17, further comprising:
a second dielectric layer disposed over a top side of the second conductor; and
traces disposed over the second dielectric layer and above the second conductor, wherein the traces above the second conductor comprise vertical sidewalls that are substantially parallel.

20. The semiconductor device of claim 17, wherein the lateral side of the first conductor is separated from the inner wall of the first dielectric layer by a width less than about 10 micrometers.
